(19) United States
(12) Patent Application Publication
(10) Pub. No.: US 2024/0217122 A1
(43) Pub. Date: Jul. 4, 2024

(54) ENHANCED SUBSTRATE TRANSFER ARM (STA) AND PEDESTAL OF THERMAL COMPRESSION BONDING (TCB) AND INTEGRATED PROCESS USING THEREOF

(71) Applicant: Intel Corporation, Santa Clara, CA (US)

(72) Inventors: Long Thanh NGUYEN, Ho Chi Minh City (VN); Tin DO, Ho Chi Minh City (VN); Le Hoai Bao NGUYEN, Dong Nai (VN); Phu Tuc NGUYEN, Ho Chi Minh City (VN); Hung Quy SOI, Ho Chi Minh City (VN)

(21) Appl. No.: 18/090,383

(22) Filed: Dec. 28, 2022

(51) Int. Cl. B25J 15/06; B25J 9/16; B25J 11/00; H05K 3/36

(52) U.S. Cl. CPC B25J 15/0683; B25J 9/1687; B25J 11/005; B25J 11/0095; H05K 3/36

(57) ABSTRACT

This disclosure describes enhanced substrate transfer arm (STA) and pedestal designs related to a thermal compression bonding process. The designs include multiple row patterns of the STA and the pedestal used to: pick up a first substrate row from a first row of a tray; place the first substrate row onto a first row of a bond stage corresponding to the first row of the tray; pick up a second substrate row from the tray; place, using the suction cups, the second substrate row onto a remaining empty row of the bond stage; pick up the first substrate row after thermal bonding from the bond stage; place the first substrate row after thermal bonding onto the tray; when all substrates from the tray have been thermally bonded, pick up a last substrate row after thermal bonding from the bond stage; and place the last substrate row onto the tray.

### TECHNICAL FIELD

This disclosure generally relates to devices, systems, and methods for integrated circuit manufacturing and, more particularly, to a maximized thermal compress bonding tool run rate for manufacturing integrated circuits.

### BACKGROUND

Thermal compress bonding is a technique used in die attachment to overcome failures, but may result in a slower run rate compared to other techniques. When using only single dice bonding on a substrate package, the bonding time may be insufficient and may be too high risk to limit thermal compress bonding.

### BRIEF DESCRIPTION OF THE DRAWINGS

FIG. 1A illustrates example substrate transfer arm (STA) movement and rotation to pick and place one row per time between cover opening stations (COS) and bond stages (BS), in accordance with one or more example embodiments of the present disclosure.

FIG. 1B shows an image of an example STA, in accordance with one or more example embodiments of the present disclosure.

FIG. 1C shows an image of the example STA from FIG. 1B being used to hold a substrate, in accordance with one or more example embodiments of the present disclosure.

FIG. 1D illustrates an example tray onto which the STA of FIGS. 1B and 1C may pick and place rows of substrates, in accordance with one or more example embodiments of the present disclosure.

FIG. 2 is a graph showing first pocket material handling time (MHT) comparisons between single-die and two-die products, in accordance with one or more example embodiments of the present disclosure.

FIG. 3 illustrates example pedestal designs, in accordance with one or more example embodiments of the present disclosure.

FIG. 4 illustrates example STA designs, in accordance with one or more example embodiments of the present disclosure.

FIG. 5A illustrates an example BS vacuum system control, in accordance with one or more example embodiments of the present disclosure.

FIG. 5B illustrates an example BS vacuum system control with an enhanced pedestal concept, in accordance with one or more example embodiments of the present disclosure.

FIG. 6A illustrates an example STA vacuum system control, in accordance with one or more example embodiments of the present disclosure.

FIG. 6B illustrates an example STA vacuum system control with an enhanced STA concept, in accordance with one or more example embodiments of the present disclosure.

FIG. 7 illustrates example tool software plug and play control sequences for STA and pedestal concepts, in accordance with one or more example embodiments of the present disclosure.

FIG. 8A is an example STA auto calibration algorithm for STA and pedestal concepts, in accordance with one or more example embodiments of the present disclosure.

FIG. 8B is an example STA auto calibration algorithm for enhanced STA and pedestal concepts, in accordance with one or more example embodiments of the present disclosure.

FIG. 9 illustrates example Design Rule of Sizes in enhanced STA and pedestal concept designs, in accordance with one or more example embodiments of the present disclosure.

FIG. 10 illustrates an example STA vacuum flow control, in accordance with one or more example embodiments of the present disclosure.

FIG. 11 illustrates an example STA vacuum flow control process, in accordance with one or more example embodiments of the present disclosure.

FIG. 12 illustrates an example BS vacuum flow control, in accordance with one or more example embodiments of the present disclosure.

FIG. 13 illustrates an example BS vacuum flow control process, in accordance with one or more example embodiments of the present disclosure.

FIG. 14 is an example tool row-mapping and calibration algorithm for enhanced STA & pedestal concept designs, in accordance with one or more example embodiments of the present disclosure.

FIG. 15 illustrates an example STA to BS pick and place sequence, in accordance with one or more example embodiments of the present disclosure.

FIG. 16 illustrates a flow diagram of an illustrative process for enhanced thermal compress bonding using enhanced STA and pedestal designs, in accordance with one or more example embodiments of the present disclosure.

FIG. 17 depicts a block diagram of an example machine upon which any of one or more techniques (e.g., methods) may be performed, in accordance with one or more example embodiments of the present disclosure.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

TCB (Thermal Compression Bonding) is an advanced technology of attaching die in semiconductor wafer bonding. Two metals are brought into atomic contact by applying both heat and force. The atomic interaction between the materials causes them to stick together. However, use of TCB results in a slower run rate compared to CAM (Chip Attach Module) and, it can be challenging in TCB to eliminate any risks of run rate degradation at a module.

In semiconductor manufacturing, TCB may include heating a die held by a bonding tool (e.g., using a heater on the bonding tool). When the die is heated sufficiently to melt solder of the die, a compression force applied to the die may be reduced, and then the solder may be brought into contact with a substrate. The bonding tool may cool the temperature to solidify the solder to the substrate. A pick and place (PnP) machine may align the substrate with openings for solder joints on the die. A substrate transfer arm (STA) may pick up and place substrates from trays for use in the TCB process.

In the MOR (Metric of Record) validation (MORv), a TCB module has revealed that there were three main factors that limit run rate of the TCB bonders and directly impact TCB MORv: 1st—bonding time limiter (e.g., the time for the bond head to bond the die to the substrate), 2nd—STA (Substrate Transfer Arm) movement and pre-heat time limiter (e.g., the time for the machine to prepare and pre-heat a new substrate on the pedestal before bonding), 3rd—Sub-tool Cycle Time limiter (e.g., time for spraying flux in a sub-machine and transfer between sub-machines before material comes into the TCB machine). In an ideal state, bonding time may be preferred as a limiter to quantify the best MORv of products. That ideal state is met while TCB running products with two or more dices type bonding on a substrate. Increasingly, there are more products that only have one dice bonding on a substrate package. With only one dice bonding, the bonding time is not enough to cover STA movement time plus Preheat time, the second factor is remarkable and can be a high risk to limit TCB bonders utilization.

The STA movement time refers to the time from picking units (e.g., completed bonding) from the bond stage to placing a new row (e.g., bare substrates) on the same bond stage.

The pre-heat time refers to the time from when substrates are placed on the pedestal to the start of bonding. It is a fixed duration controlled by a product recipe to ensure quality of flux activation.

The bonding of the die-substrates on a bond stage begins post-completion of the preheat time.

To maximize the operational effectiveness, concerns regarding reducing the STA movement time to increase MOR (metric of record) while maintaining the same as quality of single die products. A current configuration of the tool only allows the STA to pick/place one row per time from COS (Cover Opening Station—the place where the tray is located and secured for the STA to pick up substrates from the tray) to BS (Bond Stage—the place where die bonding occurs after the STA has placed a substrate onto the pedestal on the Bond Stage), and both Bond Stages are processed in an alternating sequence. In this manner, the general process is for the STA to pick up substrates from a tray held by a COS, and place the substrates onto the pedestal of a BS, where subsequent die bonding may occur.

Using the current tool configuration that only allows the STA to pick and place one row per COS to BOS, the total cycle time for one cycle of STA pick and place (PnP) between COS and BS is around 34 seconds(s). Basically, this is a fixed value because motor speed is the same for all products and may be a constant as a tool setting. The preheat time is also standardized (e.g., at 30 seconds) for almost all products and overlapped a part of STA cycle time. In total, STA cycle time plus Preheat time is approximately 35-60 (seconds) (60 seconds for changing new tray). Meanwhile, the bonding time of single dice products are from about 15 (seconds)—Hot Release profile to 35 (seconds)—Cold Release profile. With that situation, the bond head needs to wait on average about 25-30 seconds to start bonding each row on each BS. The significant MHT (Material Handling Time) gap was increased on first pocket and breaks the cascading process while switching between left and right BS and degrading TCB's MORv. For example, the MHT of the first pocket may be impacted by STA and preheat time while processing at TCB between some two-Die products and Single Die products in a HVM (High Volume Mode).

Statistically, P50 or P75 of the first pocket MHT (e.g., waiting time to start bonding row) of a single die product is already higher than row bonding time, and the first pocket MHT gaps are costing TCB consumption and waste the idling time in a cascading process to proceed to the next row. In contrast, the two-Die products have MHT of first pocket that is smaller than total Row Bonding Time (e.g., Row-level throughput time), which means bonding time is treated as a main consumer in the bonder and the tool does not waste time handling the material from row to row and BS to BS.

There have been ideas to improve MOR by bond profile throughput time (TPT) optimization, but there have not been any known ideas to reduce MHT in STA movement because a majority motion time cannot be adjusted in tool motion steps. Some delay time settings (e.g., “a” Item to “f” item) can be manipulated, but they are not large enough to effect and cover the gap because of overlapping during the process, while changing them can increase quality risk for STA pick and place. So far, there is not an effective way to improve STA cycle time—top one of bonder limiters. Table 1 below shows a summary of STA movement time and editable settings.

TABLE 1
Summary of STA Movement Time and Editable Settings:

| | | Time | | Accumulative | | | | Time |
|---|---|---|---|---|---|---|---|---|
| Step | Motion | (ms) | Formula | (ms) | Parameters | Item | | (ms) |
| 1 | COS to BS | 2400 | | 2400 | COS | A | Place Scrub | 200 |
| | | | | | | | Delay | |
| 2 | DDLO Align | 4200 | | 6600 | | B | Hold Delay | 500 |
| | Pedestal | | | | | | | |
| 3 | Pick from BS | 3400 | 2900 + e | 10000 | BS | c | Hold Delay | 3500 |
| 4 | BS to COS | 4500 | | 14500 | | d | Pre Vac | 500 |
| | | | | | | | Delay | |
| 5 | Place to COS | 2200 | 600 + | 16700 | Universal | e | Pick Delay | 500 |
| | | | (3*a) + b + f | | | | | |
| 6 | COS to COS | 1200 | | 17900 | | F | Blow Time | 500 |
| 7 | Pick from COS | 2900 | 2400 + b | 20800 | | | | |
| 8 | COS to BS | 2400 | | 23200 | | | | |
| 9 | DDLO align | 4200 | | 27400 | | | | |
| | pedestal | | | | | | | |
| 10 | Place to BS | 7100 | 600 + | 34500 | | | | |
| | | | c + d + f | | | | | |
| 11 | BS move delay | 1500 | | 34600 | | | | |
| 12 | DDLO align | 8000 | | 44000 | | | | |
| | substrate | | | | | | | |

From media tray density, engineers have carefully reviewed design rules to maximize the number of pockets per rows to increase as much as row-level bonding time and reduce the effect of STA plus preheat time at TCB. This is a verification action, and the majority of it cannot affect much the product designs because of a higher priority from platform demands.

In one or more embodiments, studies on product collateral, Tool Supplier configuration and software (SW) changes to publish a new STA and Pedestal design concept to maximize TCB run rate include: (1) New concept of Pedestal design: Add one more row-pattern and rework Pedestal vacuum line to support pick and place cascading two rows on a same Bond Stage. (2) New concept of STA design: Add one more row-pattern for STA pick and place (PnP) handling and rework STA vacuum line to support pick and place cascading two rows on a same Bond Stage. (3) Vacuum control system and SW control algorithms changes: change in STA vacuum control system, BS vacuum control system, SW control algorithms change to enhance PnP process for new STA and Pedestal designs. The combination of new Pedestal (e.g., a heater plate on which the substrate may be placed) and STA design will help to eliminate STA movement time, which is impacting TCB output. There is therefore a chance to reduce MHT of products and result in a cost saving by reducing forecast tool consumption in SDA review.

In one or more embodiments, the enhancements herein include a new concept including tool software configurations and collateral design changes to improve output and cost savings for single-die products at TCB.

By current design, the Pedestal and STA of TCB allow for pick and place of only one row for each bonding cycle. An issue to solve is the impact of STA plus preheat time limiter in TCB MOR to enable cost-savings in HVM ramp for all single die products, but without modifying the pre-heat time as a quality requirement. This gives an inspiration to pursuit the studies on remove the roadblock of STA limiter in cascading process.

In one or more embodiments, an enhanced technique is to separate two-row patterns on Pedestal and STA part to utilize the current tool configuration to cascading pick & place the pre-bonding row and the post-bonding row in separated patterns at the same cycle. This idea is turned into an appropriate and feasible study design that solve some challenges/scenarios for new designs to apply in current TCB process: Scenario #1: Do these collateral designs change require any tool hardware change? The NEW Pedestal and STA concepts only require a product's collaterals design and Software Control logics upgrade to be workable on the changes. The current STA module and BS module vacuum hardware are already configured to adapt the multi-channels control in vacuum/air blow system, for example, by upgrading SW for BS and STA vacuum control. The separated row patterns on Pedestal and STA are also reused, the BS and STA module vacuum holes may be allocated at the same position to a POR (process of record) design. There is no tool hardware change in needed to apply this methodology.

Scenario #2: How do the Pedestal and STA work sequentially with 2-row patterns? The cycle for STA PnP may be stimulated for each row for one tray on one Bond Stage. Basically, STA and BS hold only one row per at a time, and the row-pattern index is not overlapped together to avoid stack up substrate during pick and place from COS to BS. The additional row-pattern enables the capability of fast-exchange on the substrate row on BS, allowing early preparing and preheating new row on finished BS while tool bonding on remain BS. The row-pattern index on BS or STA is defined to map to a media row index by a new algorithm concept. After defining the mapping index, SW will sequentially select a media row index from which to pick STA row-pattern index and place to a Pedestal row-pattern index.

Scenario #3: Does the new concept of STA and Pedestal violate any existing design rule (DR) (e.g., Tool DR, Pedestal DR, STA DR, JEDEC (Joint Electron Device Engineering Council) Tray DR, etc.), for example when the new STA size in X seems larger than POR? Some research has ensured no violation to current design rules by defining A, B and C parameters rules that apply for Pattern KOZ (keep-out-zone) area and Vacuum KOZ area. To minimize the risk, these parameters are not only defined by using the safest requirements from existing DR, but also prove that the enhancements herein are applicable with no additional risks. Table 2 below shows a summary of parameters and concept definitions for the STA and Pedestal.

TABLE 2
STA and Pedestal Parameters and Concept Definitions:

| | | | | Tool | New |
|---|---|---|---|---|---|
| Param- | Concept | Media tray | Pedestal | Limita- | concept DR |
| eter | Definition | DR | DR | tion | requirement |
| A (mm) | Max | 106.6 | 120 | 120 | 106.6 |
| | Pattern/ | | | | |
| | Vacuum | | | | |
| | KOZ in X | | | | |
| B (mm) | Max | 295.3 | 294 | 297 | 294 |
| | Pattern/ | | | | |
| | Vacuum | | | | |
| | KOZ in Y | | | | |
| C (mm) | Row | Minimum 8 mm | N/A | N/A | Follow row |
| | Spacing | tray pocket | | | spacing in |
| | in X | spacing | | | JEDEC tray |
| | | (substrate edge | | | drawing |
| | | to substrate | | | |
| | | edge) | | | |

In one or more embodiments, the new STA in X (e.g., 125 mm) is larger POR, but this STA size is already used by another platform (e.g., Strip products) without issue. So, the idea with row-pattern adding and extended Pattern/Vacuum KOZ in X is still safe in X dimension in this concept.

Scenario #4: How do we control the vacuum for row patterns in new STA concept? The Current STA module is already separated into two channels with two vacuum holes. In one or more embodiments, by reworking the inside vacuum lines for each channel, STA can provide two vacuum systems independently for each row pattern. The present disclosure also describes the change of STA Vacuum Control Board that the switch control will recognize both the selecting row to control (0/1) and its PnP status (Vacuum/Blow—1 or Normal—0). Example, X-Y variables stand for Solenoid CH1 and Solenoid CH2 On (1)/Off (0) status. The switch control will be able to control the specific solenoid based on the PnP sequence to turn on or off solenoid by XY in {00, 01, 10, 11} depend on PnP status and vacuum/air blow/normal from vacuum generator or air blow supply. Inside the hardware, the solenoids, vacuum generator, and air blow control are already separated by control input, pressure reading, and flow meter sensor to support monitoring the vacuum/air blow system for two channels. So, the scenario is possible by using enhanced vacuum control logic.

Scenario #5: How do we control the vacuum for row patterns in new Pedestal concept? Similar to the STA module, the current BS module is already separated into four channels with four vacuum holes. In one or more embodiments, by reworking the inside vacuum lines for each channel, BS module can provide two vacuum systems independently for each row pattern. The present disclosure describes the change of BS Vacuum Control Board that the switch control will recognize both the selecting row to control (0/1) and its PnP status (Vacuum/Blow-1 or Normal 0). Example, X-Y-Z-T variables stand for BS Solenoid CH1, CH2, CH3 and CH4 On (1)/Off (0) status. The switch control will be able to control the specific solenoid based on the PnP sequence to turn on or off solenoid by XYZT in {0000, 0011, 1100, 1111} depend on PnP status and vacuum/air blow/normal from vacuum generator or air blow supply. Inside the hardware, the solenoids, vacuum generator, and air blow control are already separated by control input, pressure reading, and flow meter sensor to support monitoring the vacuum/air blow system for 4 channels. So, the scenario is possible by using enhanced vacuum control logic.

Scenario #6: How does the new STA and Pedestal concept work on multiple products with different number of rows in product's JEDEC tray? The idea is to support the products that have number of rows in JEDEC tray from two rows or higher. Generally, on “A-B-C” design rules (e.g., scenario #3), the new STA and Pedestal design concept can support products with pocket size up to 49.3 mm×143 mm and can apply to other products.

Scenario #7: How does new concept control the STA to BS placement while adding one more row pattern to not create substrate LSC (Land Side Capacitor) damage and ensure that the STA does not over move out of the JEDEC tray or row-patterns? For multi-row control in STA and Pedestal, the tool calibration is redefined to ensure STA does not move out of the JEDEC tray and facilitates PnP properly between STA and BS row pattern. A new algorithm for tool calibration and pick and place selection may be used. The algorithm defines and maps the media row index be picked and placed by STA row-pattern index to BS row-pattern index. The STA and BS row-pattern index is also mapped in parallel, meaning the STA row-pattern at index of 0 may pair to BS row-pattern at index of 0 and vice versa.

Scenario #8: Does the new concept introduce new risk of suction cup damage while STA is placing only one substrate row in a two-row pattern and with more frequency to closely touching the pedestal? For a STA placing only one substrate row in two-row patterns, because there is only one STA-Z motor, STA would move the same Z for both rows. Therefore, the remainder of the STA not holding a substrate will not touch the pedestal while STA remains at Z-height with a spacing a gap equal to the substrate thickness. Besides that, in PnP sequence control, the machine may be controlled to place the new substrate row on a pedestal first, then pick up the completed substrate row on the remaining row pattern. Therefore, the suction cup of the STA will not touch the pedestal surface during the STA pick and place process. In addition, there is another suction cup type developed to provide a longer lasting pick head. The new suction cup may reduce the risk for this scenario.

Scenario #9: How do we make sure the new configuration for STA and Pedestal is not impacted by Bond Head attachment processing? The changes of the new STA and Pedestal effects the substrate row pick and place process between COS and BS only; there is no change requirement for the bond head process. At one time, the BS has only one available substrate row to activate the bonding sequences, and the new row-pattern added to save idling time exchanges a new row on that BS with no effect to the bonding process.

Scenario #10: Why do the new STA and Pedestal not pick or place two rows at the same time, and only allow placing one available substrate row on Pedestal? The placement of both rows at the same time will increase the risk of the reject rate increasing by current sit-time requirement of products in sustaining mode. To not increase risk in the bonding process and sustain yield loss, the change is designed to use a faster row preparing process and eliminate STA movement time, and allow for alternating the active substrate row on the bond stage by the remaining row-pattern in the design. Placement substrate by row-pattern index will reduce the risk placement offsets compared to picking and placing both rows at the same time.

Scenario #11: How does the new concept increase TCB run rate? The first pocket MHT P75 and P50 (s) of single die product are 39.6 (seconds) and 27 (seconds), respectively, longer than 14.1 (seconds) of total row processing time. By stopwatch measurement, one STA cycle time is 34 (seconds), including: Time for STA to move from COS to BS to pick the units: 8 s (Step 1), time to for STA replace units to JEDEC tray at COS: 9 seconds (Step 2), time for STA to pick 2nd round substrate to put into BS: 9 seconds (Step 3), time for STA to move from COS to BS and place the substrate: 8 seconds (Step 4). In a new pick and place sequence change herein, the STA cycle time is saved 25 (seconds) from 34 (seconds) to 9 (seconds) in the 3rd step for cascading row processing. The 9 seconds for exchanging the new row is also overlapped in preheat time of substrate and bonding time from remain Bond Stage. That means STA movement is eliminated in a cascading process of TCB. With that situation, depending on a product's row process time and bond profile type, it can be evaluated that: 1 Dice Hot Release products: amount of STA cycle time (s)—Total row process time (s) seconds saved for each cascading row in tray, with average savings of about 10 seconds per row. 1 Dice Cold Release products: eliminate STA movement time and preheat time limiter, the bonding time is the new limiter because bonding time (˜35 seconds) is longer than preheat time (30 seconds). In P75 calculation, 5 seconds per row may be saved. 2 Dices products: the bonding time is still the limiter as bonding time is longer than preheat time.

Currently, there may be more than a dozen single dice products running in a site (e.g., both Cold Release products and Hot Release products), and the new STA and Pedestal design concept will be estimated to gain: A site having 13 single dice products (e.g., 9 Cold Release products and 4 Hot Release products) and maximum SDA (Supply Demand Analysis) for tool count requirement in a year are 20 TCB links. Hence, there may be savings of up to 6 TCB links, meaning saving millions of dollars by maximizing bonding time with STA movement time eliminated from the cascading process. The total TCB links in some sites may be double, so it may be estimated that a 36 million USD cost savings is achieved by MORv improvement in the enhanced design concept herein.

The concepts herein provide a “Maximize TCB (Thermal Compress Bonding) Tool run rate by New Pedestal and STA design” concept to optimize the process and increase run rate with huge cost-saving for Intel manufacturing. For flux-less configuration in next TCB generations, the sub-tool cycle time limiter may be removed, and STA movement time and preparing time limiter may be the largest challenges for module development and improvement. The idea could also be a consideration to resolve that obstacle, enabling millions of dollars in capital cost avoidance.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

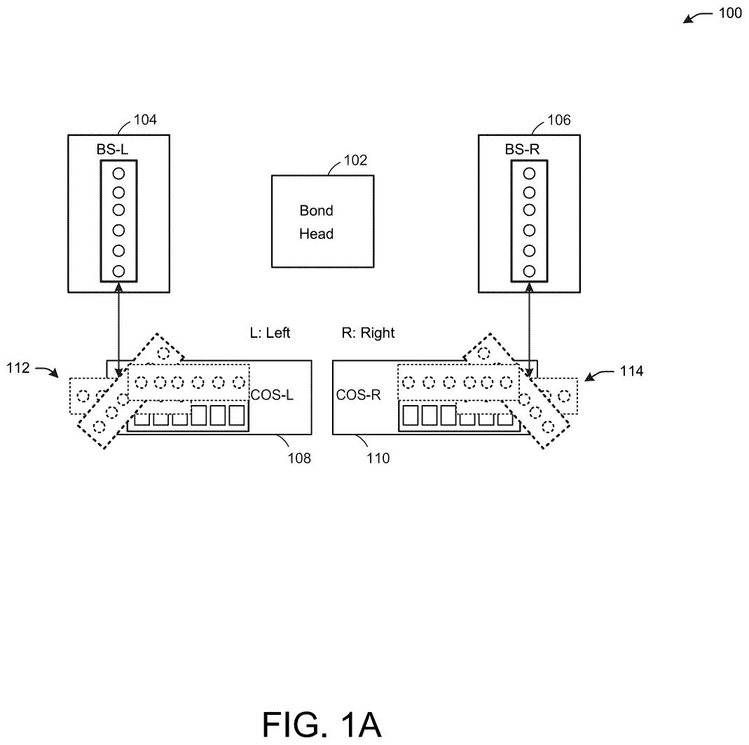

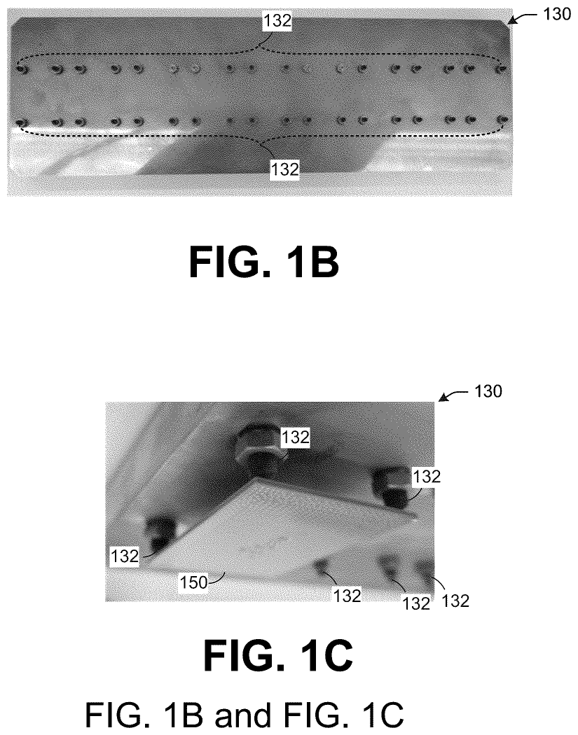

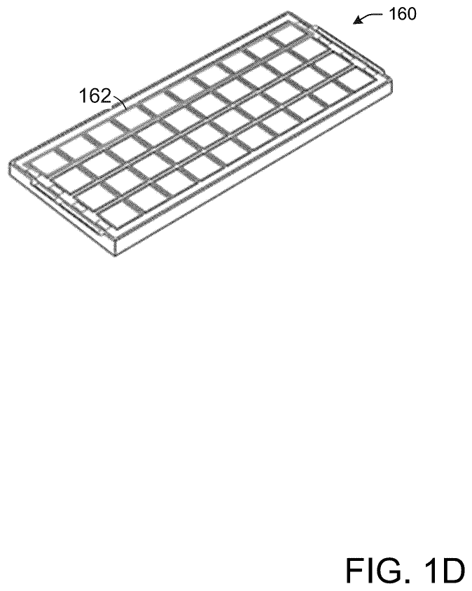

FIG. 1A illustrates example substrate transfer arm (STA) movement and rotation 100 to pick and place one row per time between cover opening stations (COS) and bond stages (BS), according to some example embodiments of the present disclosure.

Referring to FIG. 1, a bond head 102, bond stages (BS-L 104 for left BS, BS-R 106 for right BS), cover opening stages (COS-L 108 for left COS and COS-R 110 for right COS) are shown along with left and right STAs (STA-L 112 and STA-R 114). Each of the STA arms (STA-L 112 and STA-R 114) is shown moving/rotating to different positions for pick and place between respective COS and BS.

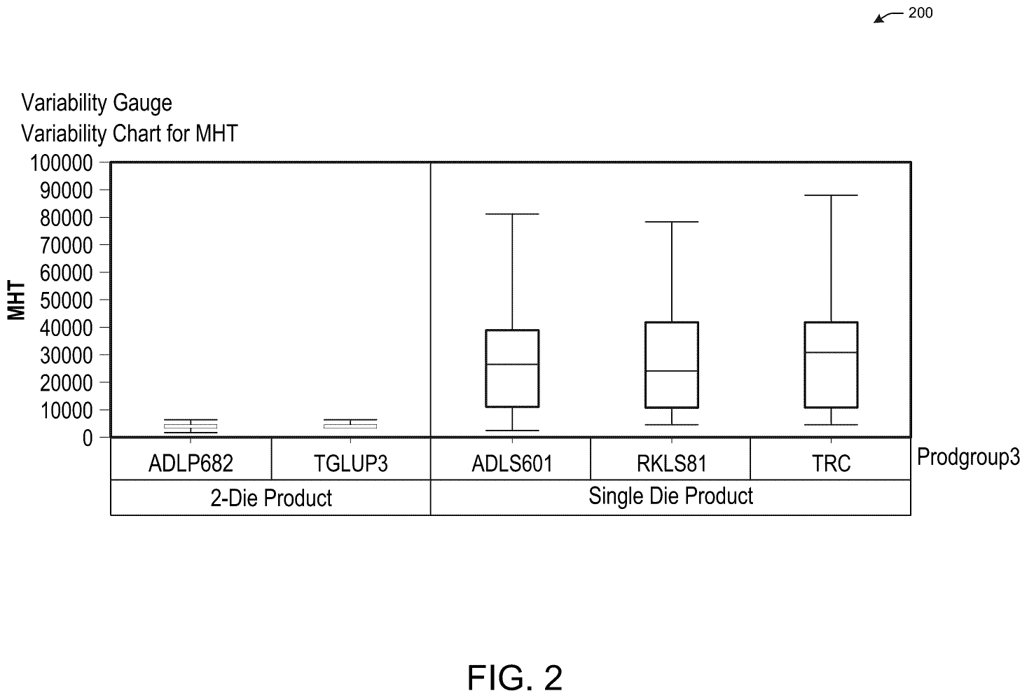

In one or more embodiments, the total cycle time for one cycle of STA pick and place (PnP) between COS and BS is around 34 seconds(s). This is effectively a fixed value because STA motor speed may be the same for all products and may be constant as tool settings. The preheat time is also standardized at 30 s for almost all products and overlaps a part of STA cycle time. In total, STA cycle time plus Preheat time is approximately 35-60 (s) (60 s for changing new tray). Meanwhile, the bonding time of single dice products are from about 15 (s)—Hot Release profile to 35 (s)—Cold Release profile. With that situation, the bond head 102 needs to wait on average about 25-30 s to start bonding each row on each BS. The MHT gap was increased on 1st pocket and breaks the cascading process while switching between left and right BS, and degrades TCB's MORv. For example, FIG. 2 illustrates how the MHT of 1st pocket was impacted by STA and preheat time while processing at TCB between some 2-Die products and Single Die products in HVM (High Volume Mode).

FIG. 1B shows an image of an example STA 130, in accordance with one or more example embodiments of the present disclosure.

Referring to FIG. 1B, the STA 130 may include multiple rows of suction cups 132 with which to PnP substrates (e.g., as shown in FIG. 1C).

FIG. 1C shows an image of the example STA 130 from FIG. 1B being used to hold a substrate 150, in accordance with one or more example embodiments of the present disclosure.

As shown in FIG. 1C, four of the suction cups 132 may be used to pick up and hold a substrate 150 (e.g., using vacuum suction) at a time as a “pocket.” The STA 130 may pick up substrates in a row (e.g., using a respective row of suction cups 132 as shown in FIG. 1B) for all pockets.

FIG. 1D illustrates an example tray 160 onto which the STA of FIGS. 1B and 1C may place rows of substrates, in accordance with one or more example embodiments of the present disclosure.

Referring to FIG. 1D, the tray 160 may be referred to as a JDEC tray, which may be held by a COS (e.g., the COS-L 108 or the COS-R 110 of FIG. 1A), and may hold substrates (e.g., the substrate 150 of FIG. 1C) in rows (e.g., a row 162 as shown in FIG. 1D). The STA 130 of FIGS. 1B and 1C may pick up substrates from the tray 160, then place the substrates on the pedestal of a bond stage where for subsequent die bonding. The enhanced STAs herein reduce the STA movement and time required for this process.

FIG. 2 is a graph 200 showing first pocket material handling time (MHT) comparisons between single-die and two-die products, in accordance with one or more example embodiments of the present disclosure.

As noted above, FIG. 2 illustrates how the MHT of 1st pocket was impacted by STA and preheat time while processing at TCB between some 2-Die products and Single Die products in HVM (High Volume Mode).

Statistically, P50 or P75 of the 1st pocket MHT (waiting time to start bonding row) of single die product is already higher than row bonding time, and the 1st pocket MHT gaps are costly to TCB consumption and waste the idling time in the cascading process to proceed to a next row. In contrast, the 2-Die products have MHT of 1st pocket is such smaller than total Row Bonding Time (Row-level TPT), which means bonding time is considered a main consumer in bonding and the tool does not waste much time handling the material from row to row and BS to BS.

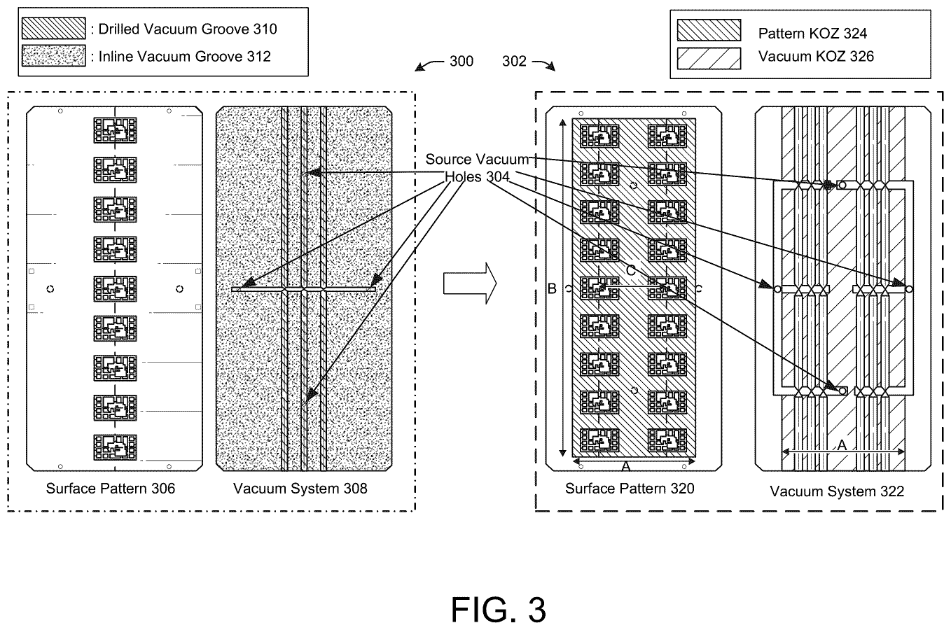

FIG. 3 illustrates example pedestal designs, in accordance with one or more example embodiments of the present disclosure.

Referring to FIG. 3, the POR 300 and an enhanced design 302 are shown. Each of the POR 300 and enhanced design 302 have source vacuum holes 304 as shown. A surface pattern 306 and vacuum system 308 of the POR 300 are shown. The vacuum system 308 has drilled vacuum grooves 310 and inline vacuum grooves 312. A surface pattern 320 and vacuum system 322 of the enhanced design 302 are shown. The surface pattern 320 may use a pattern KOZ 324, and the vacuum system 322 may use a vacuum KOZ 326.

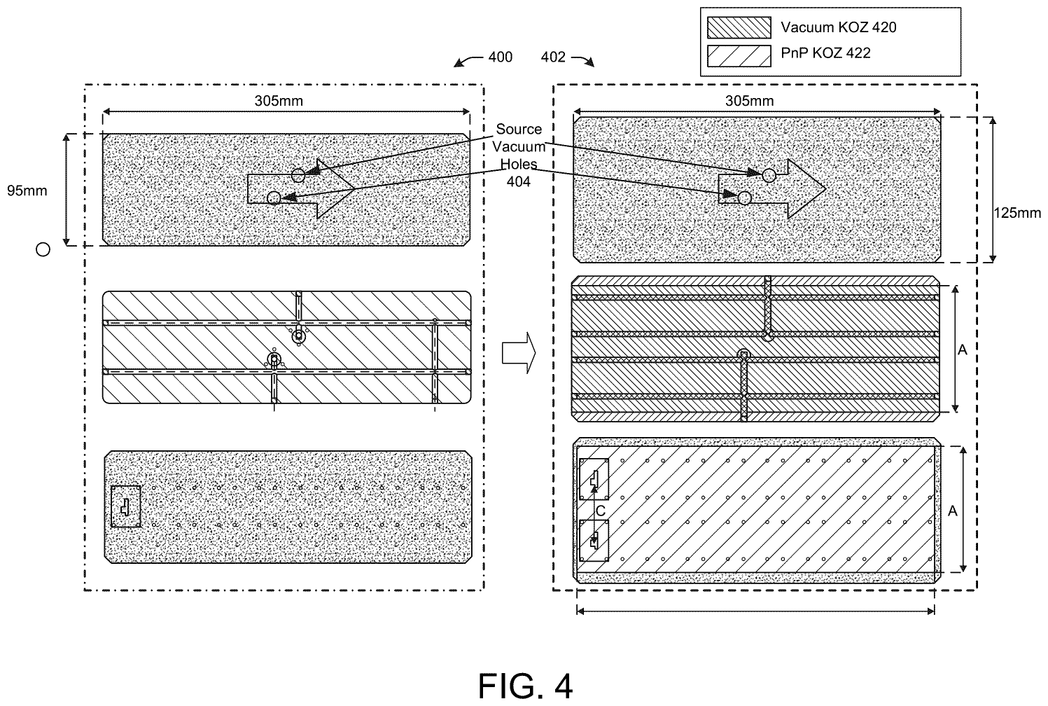

FIG. 4 illustrates example STA designs, in accordance with one or more example embodiments of the present disclosure.

Referring to FIG. 4, the POR 400 and an enhanced design 402 are shown. Each of the POR 400 and enhanced design 402 have source vacuum holes 404 as shown. A width of the POR 400 is shown as 95 mm, and a length of the POR 400 is shown as 305 mm. For the enhanced design 402, the width may expand to 125 mm as shown, and the length may remain at 305 mm as shown (e.g., for the top tool side). The enhanced design 404 may use a vacuum KOZ 420 and a PnP KOZ 422.

Referring to FIGS. 3 and 4, the separated row patterns on the enhanced Pedestal (FIG. 3) and STA (FIG. 4) designs are also reused, including the BS and STA module vacuum holes allocated at the same position as the respective POR designs. In this manner, there is no tool hardware change in need to apply this methodology.

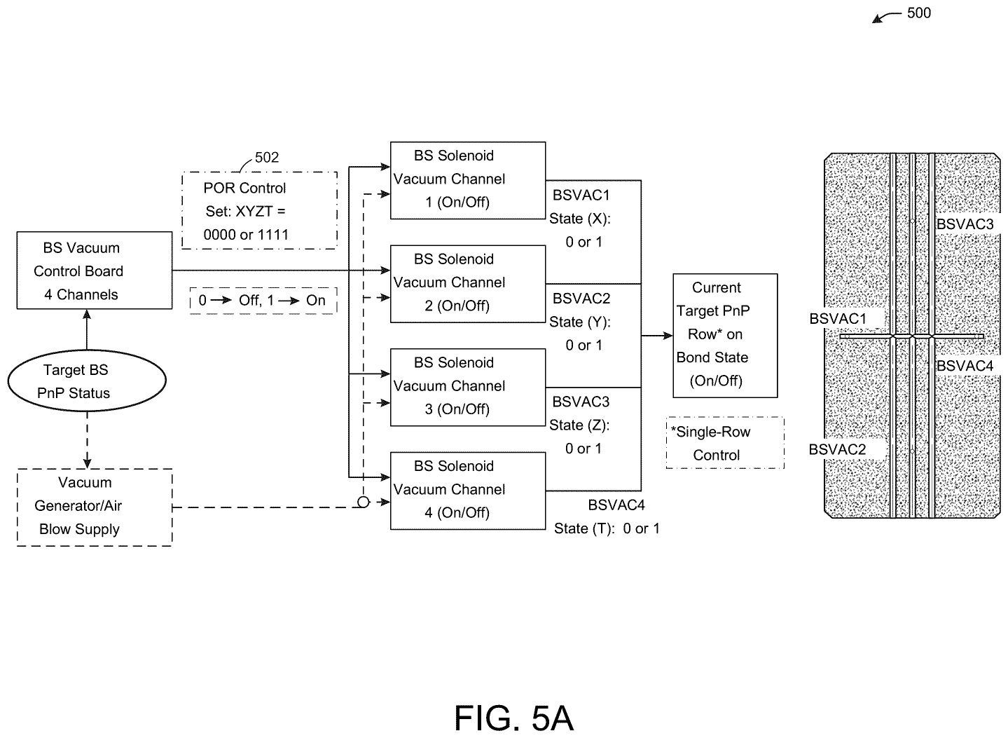

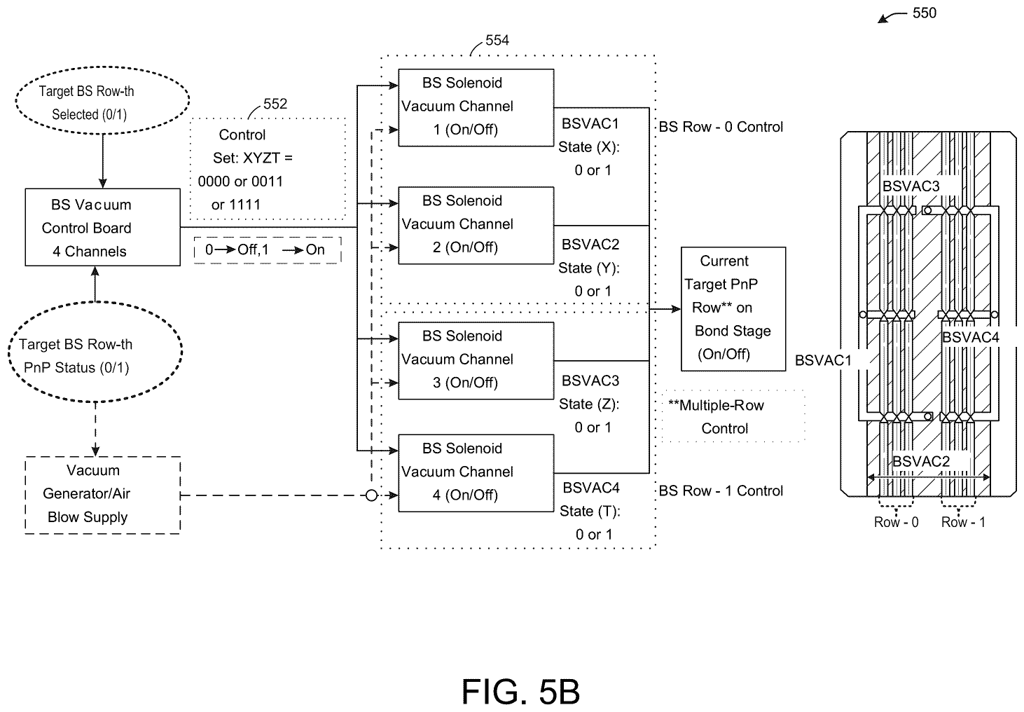

FIG. 5A illustrates an example BS vacuum system 500, in accordance with one or more example embodiments of the present disclosure.

The BS vacuum system 500 may represent the POR using a POR control set 502 (e.g., XYZT=0000 or 1111) for single row control (e.g., one row at a time for PnP), where 0 is off and 1 is on.

FIG. 5B illustrates an example flow a BS vacuum system 550 with an enhanced pedestal concept, in accordance with one or more example embodiments of the present disclosure.

In contrast with the POR of the BS vacuum system 500 of FIG. 5A, the enhanced pedestal concept may allow for multi-row control using a control set 552 (e.g., XYZT=0000, 0011, or 1111), where 0 is off, and 1 is on.

Referring to FIGS. 5A and 5B, the POR STA module and BS module vacuum hardware are already configured to adapt to use the multi-channel control in vacuum/air blow system by upgrading SW for BS and STA vacuum control. As shown in both FIGS. 5A and 5B, the BS solenoid vacuum control board has multiple channels (e.g., 1-4). The BS vacuum system 550, however, adds multi-row control to separate two-row pedestal patterns (e.g., Row-0 and Row-1 in FIG. 5B) to PnP the pre-bonding row and post-bonding row in separate patterns during a same cycle.

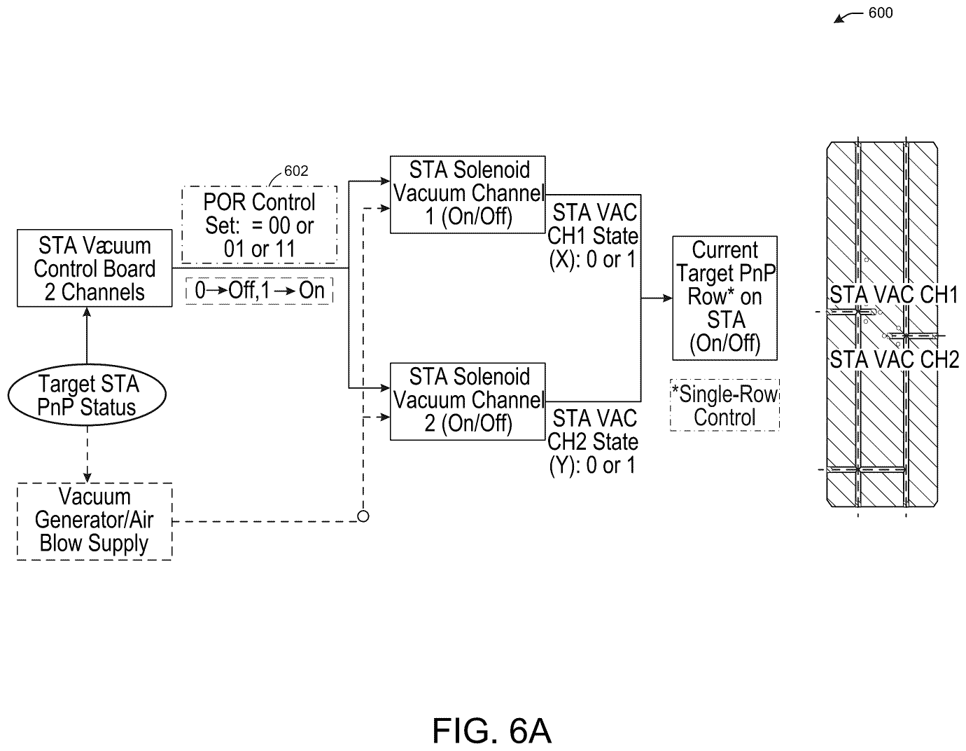

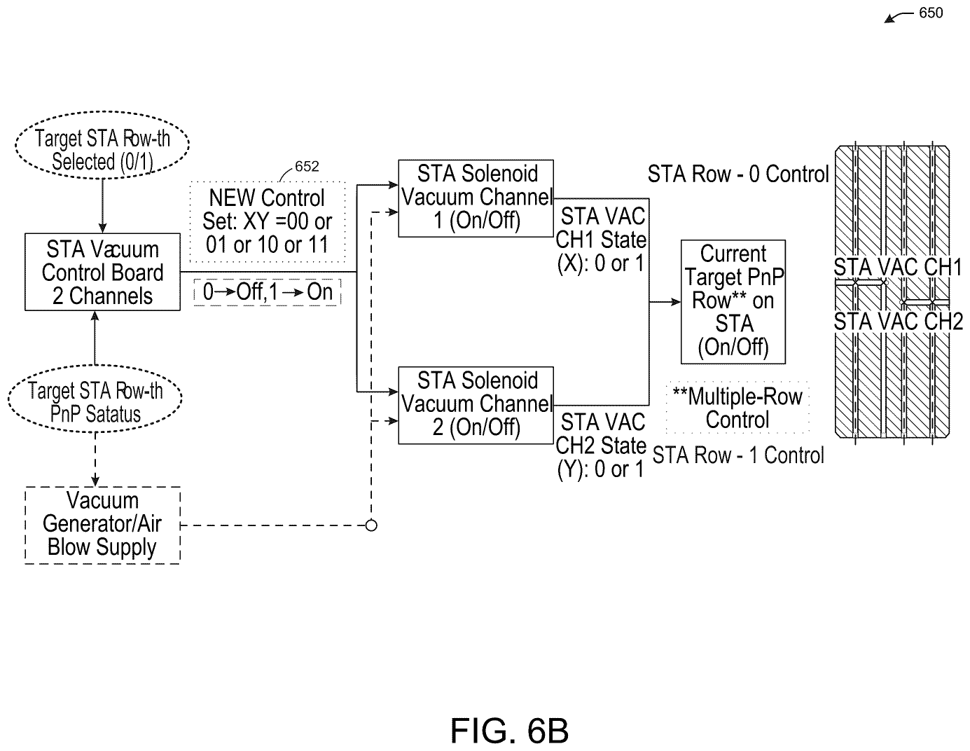

FIG. 6A illustrates an example STA vacuum system control 600, in accordance with one or more example embodiments of the present disclosure.

Referring to FIG. 6A, the STA vacuum system control 600 may represent the POR using single-row control with a POR control set 602 (e.g., 00, 01, or 11 with 0 off and 1 on).

FIG. 6B illustrates an example STA vacuum system control 650 with an enhanced STA concept, in accordance with one or more example embodiments of the present disclosure.

Referring to FIG. 6B, the STA vacuum system control 650 with an enhanced STA concept may have multi-row control using a control set 652 (e.g., 00, 01, 10, or 11 with 0 off and 1 on). The additional control set 652 combinations may allow for multi-row control to separate two-row STA patterns (e.g., Row-0 and Row-1 in FIG. 6B) to PnP the pre-bonding row and post-bonding row in separate patterns during a same cycle.

The current STA module and BS module vacuum hardware are already configured to adapt the multi-channels control in vacuum/air blow system by upgrading SW for BS and STA vacuum control as shown in FIGS. 6A and 6B.

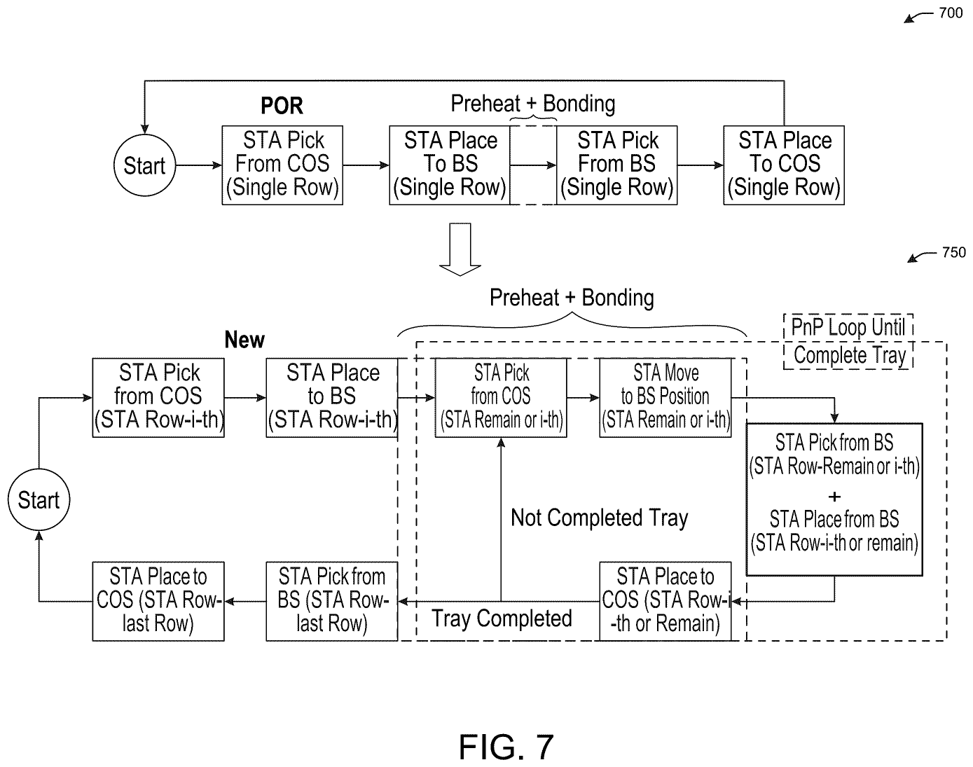

FIG. 7 illustrates example tool software plug and play control sequences for STA and pedestal concepts, in accordance with one or more example embodiments of the present disclosure.

A POR PnP control sequence 700 is shown, along with the differences with an enhanced PnP control sequence 750. In particular, the POR PnP control sequence 700 may be single-row for the STA and pedestal, whereas the enhanced PnP control sequence 750 may allow for multi-row PnP for the STA and pedestal during a same cycle.

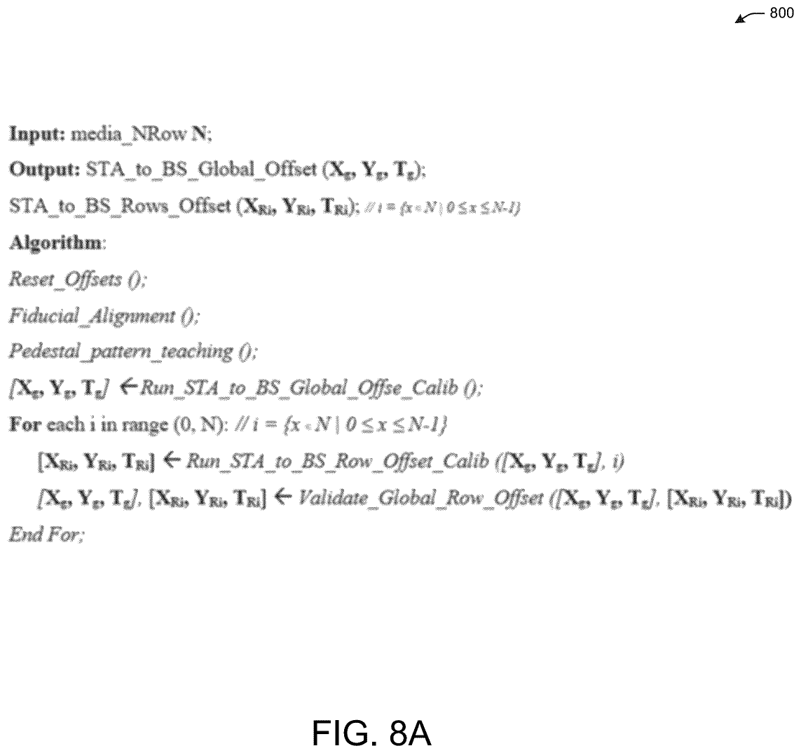

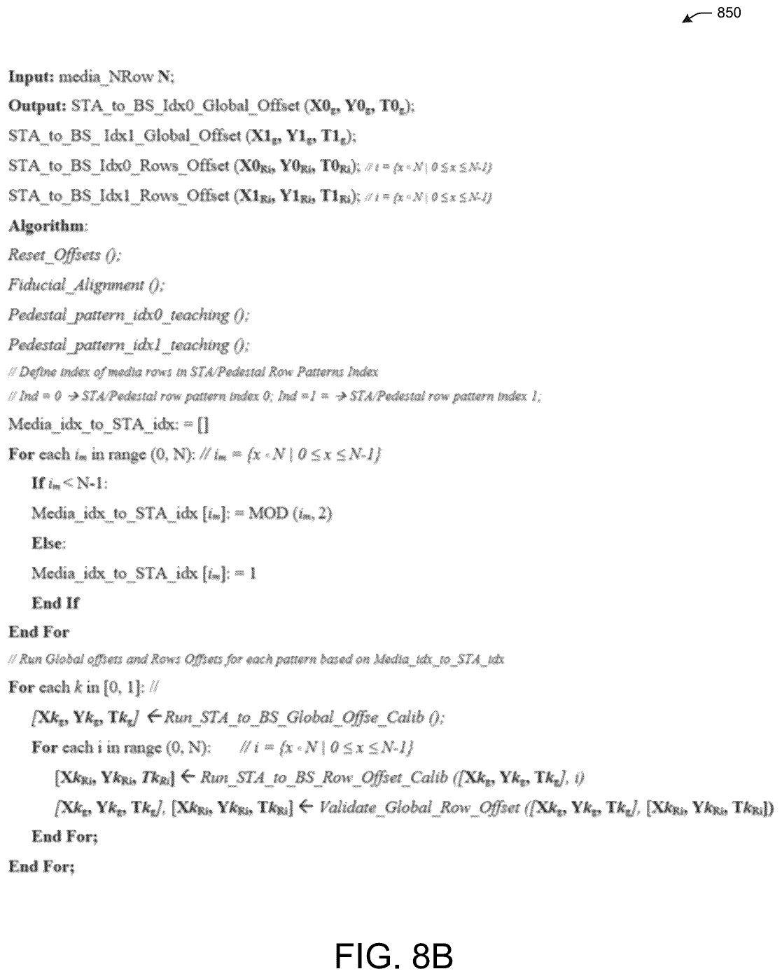

The PnP control sequences in FIG. 7 simulate the cycle for STA PnP each row for one tray on one Bond Stage. In the POR PnP control sequence 700, STA and BS hold only one row at a time and the row-pattern index is not overlapped to avoid stack up at the substrate during pick and place from COS to BS. The additional row-pattern of the enhanced PnP control sequence 750 enables the capability to fast-exchange the substrate row on BS, allow early preparing and preheating a new row on a finished BS while tool bonding remains on a BS. The row-pattern index on BS or STA is defined to map with media row index by an algorithm concept in FIGS. 8A-8B. After defined the mapping index, SW will sequentially select properly media row index to pick from a STA row-pattern index and place on a Pedestal row-pattern index.

FIG. 8A is an example STA auto calibration algorithm 800 for STA and pedestal concepts, in accordance with one or more example embodiments of the present disclosure.

FIG. 8B is an example STA auto calibration algorithm 850 for enhanced STA and pedestal concepts, in accordance with one or more example embodiments of the present disclosure.

The STA auto calibration algorithm 800 may represent the POR for single-row applications, and the STA auto calibration algorithm 850 may represent enhancements allowing for multi-row applications. The additional row-pattern of the enhanced PnP control sequence 750 of FIG. 7 enables the capability to fast-exchange the substrate row on BS, allow early preparing and preheating a new row on a finished BS while tool bonding remains on a BS. After defined the mapping index, SW will sequentially select properly media row index to pick from a STA row-pattern index and place on a Pedestal row-pattern index.

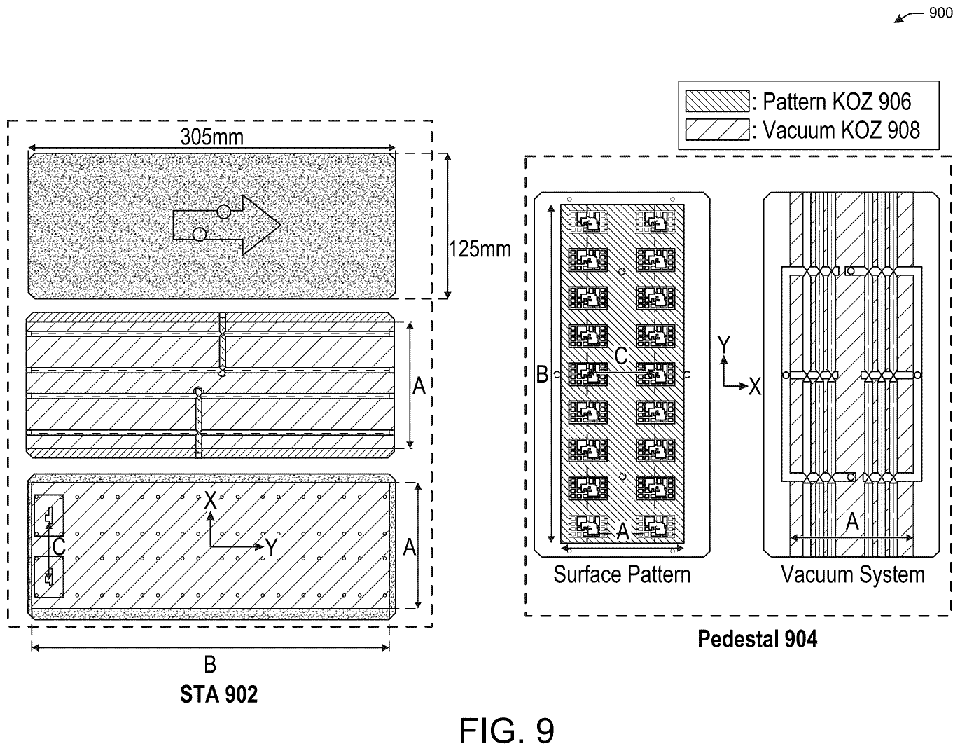

FIG. 9 illustrates example STA and pedestal concept designs, in accordance with one or more example embodiments of the present disclosure.

A STA design 902 and a pedestal design 904 are shown in FIG. 9, using a pattern KOZ 906 and a vacuum KOZ 908 as shown. The A, B, and C parameters shown may be defined based on Table 2 above, for example. The new STA in the X direction (e.g., 125 mm) is larger than for the POR, but this STA size is already used by another platform (e.g., Strip products) without issue. So, the enhancements herein to add row-patterns and extend Pattern/Vacuum KOZ in X is still safe in the X dimension in this concept.

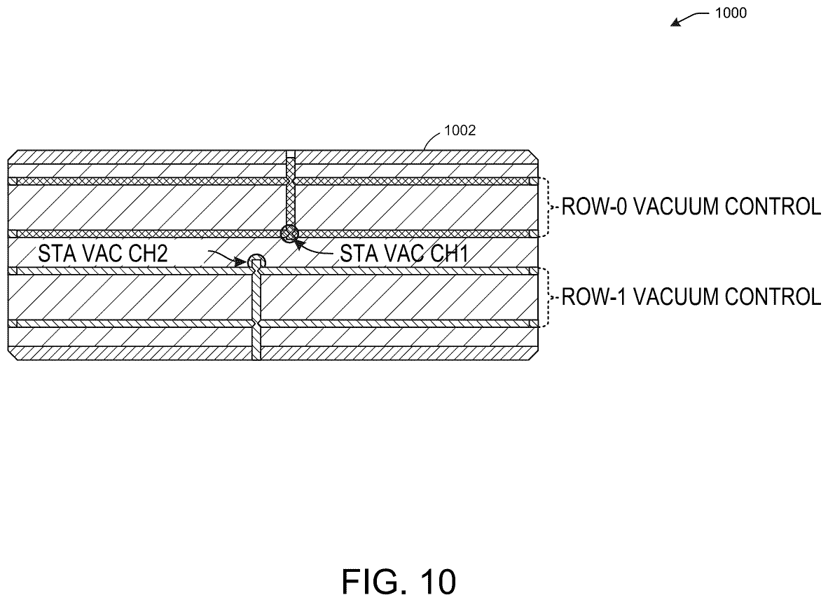

FIG. 10 illustrates an example STA vacuum flow control 1000, in accordance with one or more example embodiments of the present disclosure.

The current STA module 1002 is already separated into two channels with two vacuum holes. By reworking the inside vacuum lines for each channel, an STA can provide two vacuum systems independently for each row pattern as shown (e.g., Row-0 vacuum control, Row-1 vacuum control) for the two vacuum channels (e.g., STA VAC CH1, STA VAC CH2).

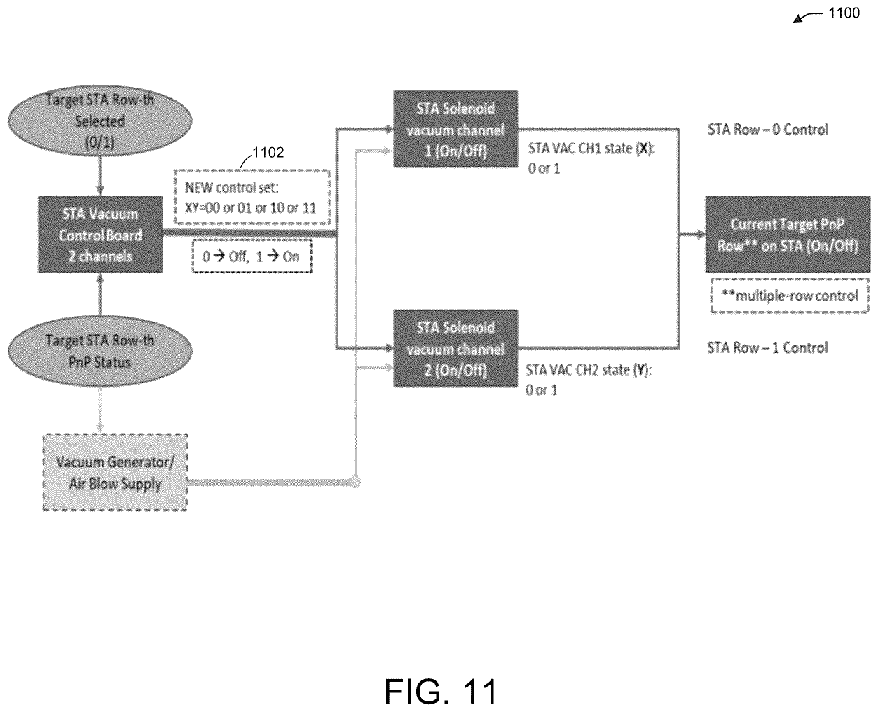

FIG. 11 illustrates an example STA vacuum flow control process 1100, in accordance with one or more example embodiments of the present disclosure.

The STA vacuum flow control process 1100 describes the change of STA Vacuum Control Board in which the switch control may recognize both the selecting row to control (0/1) and its PnP status (Vacuum/Blow-1 or Normal-0). For example, X-Y variables of the control set 1102 stand for Solenoid CH1 and Solenoid CH2 On (1)/Off (0) status. The switch control may be able to control the specific solenoid based on the PnP sequence to turn on or off solenoid by XY in {00, 01, 10, 11} depend on PnP status and vacuum/air blow/normal from vacuum generator or air blow supply. Inside the hardware, the solenoids, vacuum generator, and air blow control are already separated by control input, pressure reading, and flow meter sensor to support monitoring the vacuum/air blow system for two channels.

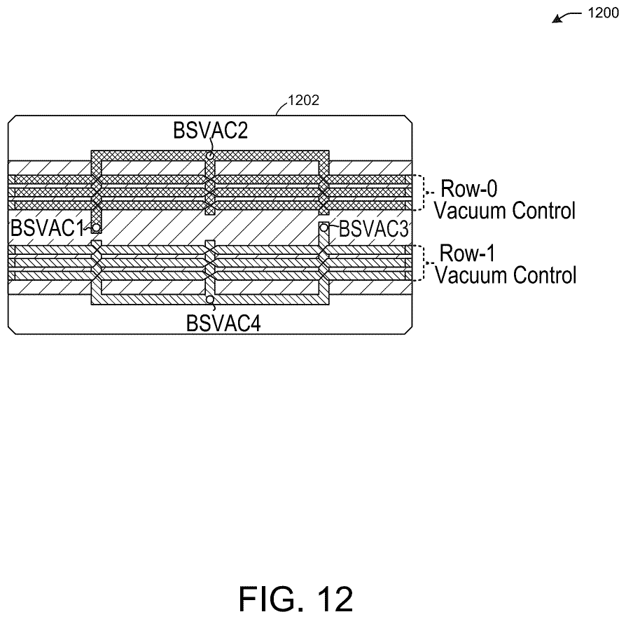

FIG. 12 illustrates an example BS vacuum flow control 1200, in accordance with one or more example embodiments of the present disclosure.

Like the STA module, the current BS module 1202 is already separated into four channels with four vacuum holes (e.g., BSVAC1, BSVAC2, BSVAC3, BSVAC4). By reworking the inside vacuum lines for each channel, BS module can provide two vacuum systems independently for each row pattern (e.g., Row-0 vacuum control, Row-1 vacuum control).

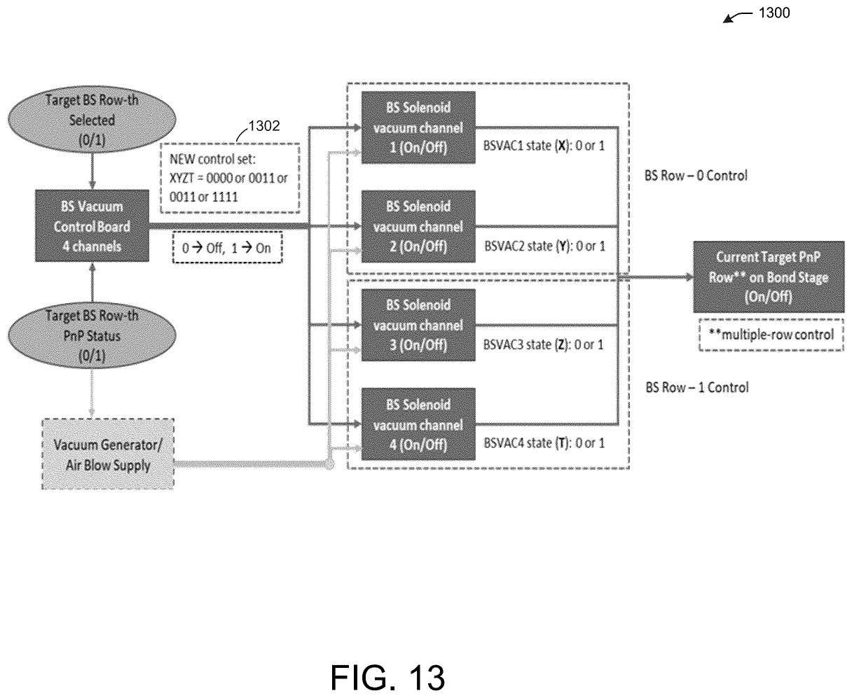

FIG. 13 illustrates an example BS vacuum flow control process 1300, in accordance with one or more example embodiments of the present disclosure.

The BS vacuum flow control process 1300 describes the change of BS Vacuum Control Board that the switch control may recognize both the selecting row to control (0/1) and its PnP status (Vacuum/Blow-1 or Normal-0). Example, X-Y-Z-T variables of the control set 1302 stand for BS Solenoid CH1, CH2, CH3 and CH4 On (1)/Off (0) status. The switch control may be able to control the specific solenoid based on the PnP sequence to turn on or off solenoid by XYZT in {0000, 0011, 1100, 1111} depending on PnP status and vacuum/air blow/normal from vacuum generator or air blow supply. Inside the hardware, the solenoids, vacuum generator, and air blow control are already separated control input, pressure reading, and flow meter sensor to support monitoring the vacuum/air blow system for four channels.

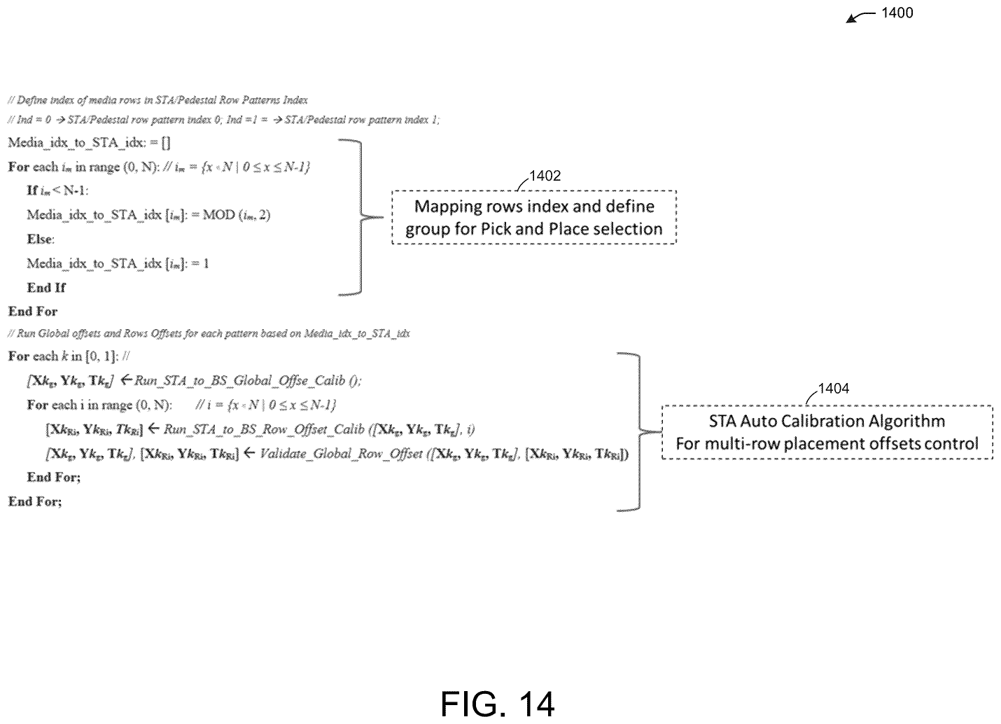

FIG. 14 is an example tool row-mapping and calibration algorithm for enhanced STA & pedestal concept designs 1400, in accordance with one or more example embodiments of the present disclosure.

For multi-row control in STA and Pedestal, the tool calibration is redefined to ensure STA does not move out of the JEDEC tray and PnP between STA and BS row pattern. The tool row-mapping and calibration algorithm 1400 for tool calibration and pick and place selection defines and maps 1402 the media row index be picked and placed by STA row-pattern index to BS row-pattern index. The STA and BS row-pattern index is also mapped in parallel, meaning the STA row-pattern at index of 0 will pair to a BS row-pattern at index of 0 and vice versa. The BS vacuum flow control process algorithm 1400 may include an STA auto calibration algorithm 1404 for multi-row placement offset control.

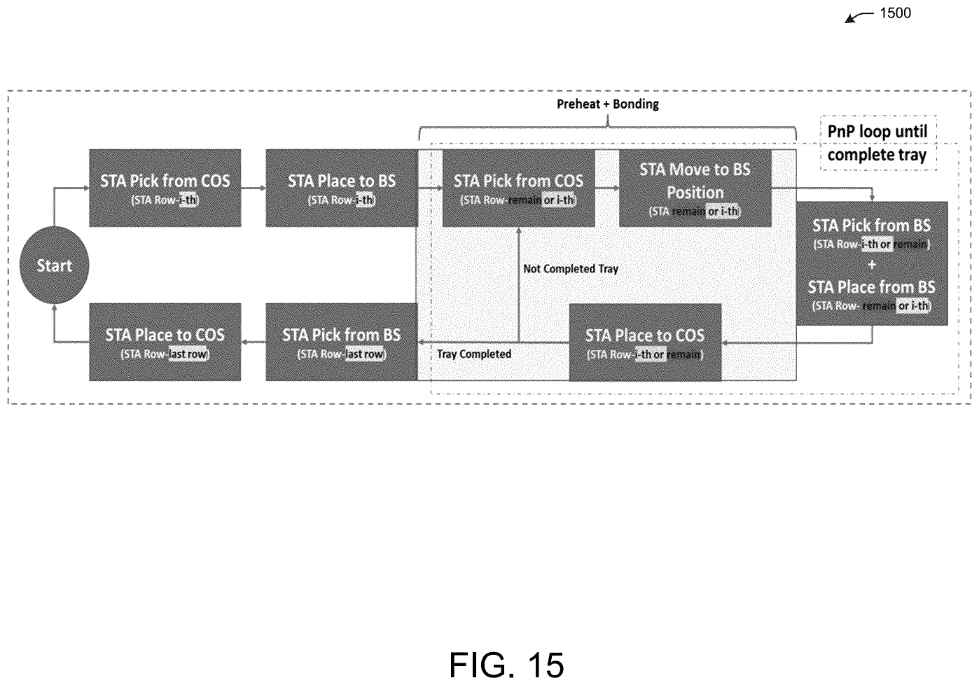

FIG. 15 illustrates an example STA to BS pick and place sequence 1500, in accordance with one or more example embodiments of the present disclosure.

In new pick and place sequence change represented by the STA to BS pick and place sequence 1500, the STA cycle time is saved 25 (s) from 34 (s) to 9 (s) in 3rd step for cascading row processing. The 9 seconds to exchange the new row is also overlapped in preheat time of the substrate and bonding time from a remaining Bond Stage. That means STA movement may be eliminated in the cascading process of TCB. With that situation, depending on a product's row process time and bond profile type, it can be evaluated that: 1 Dice Hot Release products: amount of STA cycle time (s)—Total row process time (s) seconds saved for each cascading row in tray, averagely it's saved about 10 s saved per row. 1 Dice Cold Release products: eliminate STA movement time and preheat time limiter, the bonding time is the new limiter because bonding time (˜35 s) is such longer than preheat time (30 s). In P75 calculation, we save about 5 s per row. 2 Dices products: the bonding time is still the limiter as bonding time is such longer than preheat time.

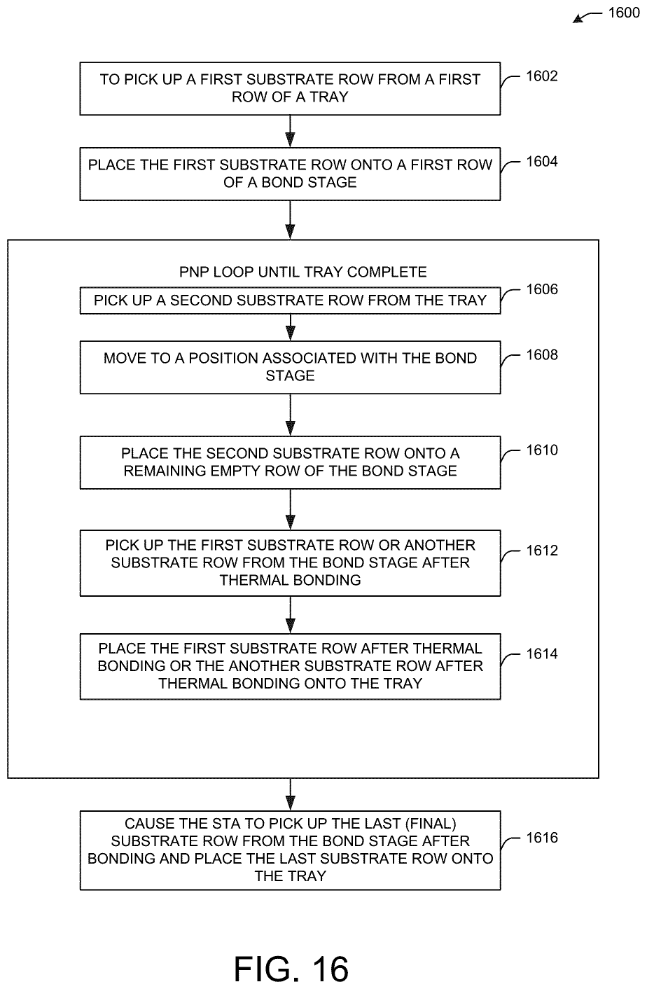

FIG. 16 illustrates a flow diagram of an illustrative process for enhanced thermal compress bonding using enhanced STA and pedestal designs, in accordance with one or more example embodiments of the present disclosure.

At block 1602, a STA (e.g., the STA 130 of FIG. 1B) may select a row of a tray (e.g., the tray 160 of FIG. 1D, held by a COS) from which to pick up a substrate (e.g., the substrate 150 of FIG. 1C) with an STA (e.g., as shown in FIG. 1C). For example, when there are multiple rows in a tray and BS, the STA may use a multi-row pattern (e.g., using the controls in FIG. 5B, FIG. 6B, FIG. 11, FIG. 13) to limit STA movement and reduce TCB time. The row patterns may use a mapping in which a given row of a COS (e.g., a row of the tray held by the COS) may map to a corresponding row of a BS (e.g., a row having index 0 of a COS may map to row having index 0 of a BS). The STA may pick up the first substrate row from the selected row of the tray held by the COS. The STA may align with the COS (e.g., the tray held by the COS) and BS to pick up the substrate row and place the substrate row based on the corresponding coordinate location of the row of the COS or BS, for example.

At block 1604, the STA may place the first substrate row onto the selected row of the BS. For the i-th row from which the COS the substrate row was picked up, the STA may place the row on the corresponding i-th row of the BS.

At block 1606, as part of a PnP loop that may repeat until the last row in the JEDEC tray is complete (e.g., based on a number of rows of the tray in the COS), the STA may pick up a second substrate row (e.g., a next row not necessarily the second physical row) from the tray on the COS. The second substrate row may be picked up from the i-th row or a remaining row of the JEDEC tray by a remaining empty row of suction cups of the STA.

At 1608, the device may cause the STA to move to a BS position (e.g., corresponding to the i-th row or a remaining row of the BS).

At block 1610, the STA may place the second substrate row onto a remaining empty row of the bond stage different than the first row of the bond stage from which the first substrate row or the another substrate row is picked up after bonding.

At block 1612, after the STA has placed the second substrate row onto the bond stage, the STA may pick up the first substrate row or another substrate row from the BS after thermal bonding (e.g., using different rows of the suction cups of the STA). In this manner, substrate row placement by the STA is improved. Blocks 1606-1610 may occur during preheating and/or thermal compression bonding of a substrate row that has been placed on the BS.

At block 1614, the STA may place the first substrate row after thermal bonding or the another substrate row after thermal bonding onto the tray. The process may repeat from block 1606 until the tray has been completed (e.g., all the substrate rows on the tray have been placed on the BS and thermally bonded). The device may cause the STA to pick up the completed bonding row from the BS, either from the i-th row or a remaining row.

At block 1616, the STA may place the final completed bonding row (the last substrate row of the tray to be bonded at the BS) onto a row of the tray on the last empty row of the tray.

It is understood that the above descriptions are for purposes of illustration and are not meant to be limiting.

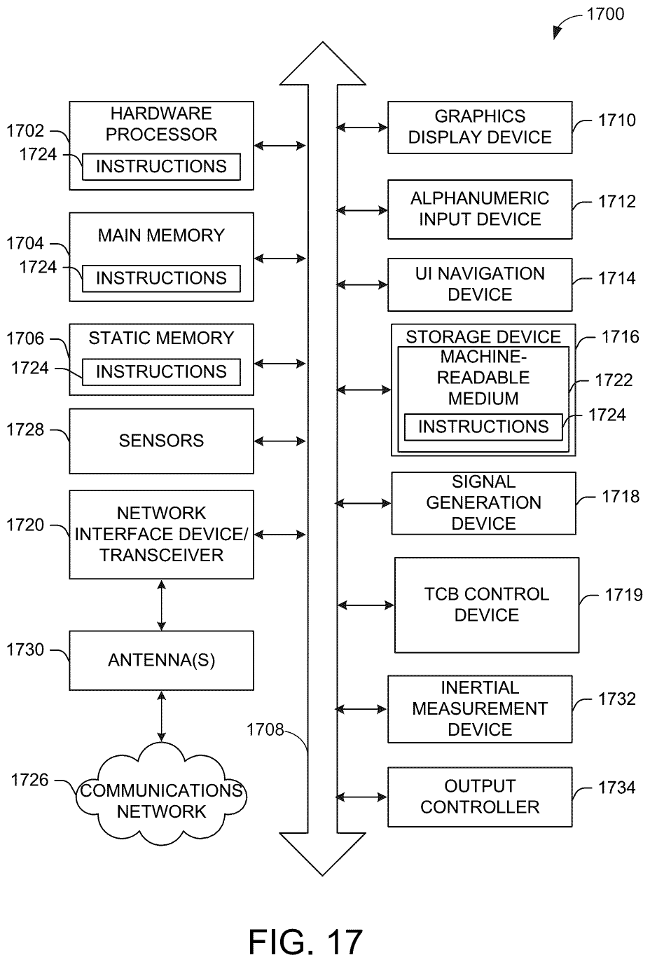

FIG. 17 illustrates a block diagram of an example of a machine 1700 or system upon which any one or more of the techniques (e.g., methodologies) discussed herein may be performed. In other embodiments, the machine 1700 may operate as a stand-alone device or may be connected (e.g., networked) to other machines. Further, while only a single machine is illustrated, the term “machine” shall also be taken to include any collection of machines that individually or jointly execute a set (or multiple sets) of instructions to perform any one or more of the methodologies discussed herein. For example, the robotic machine 1700 may include or represent components of the TCB tools and add-on modules described herein, such as the STA, bond head, and BS.

Examples, as described herein, may include or may operate on logic or a number of components, modules, or mechanisms. Modules are tangible entities (e.g., hardware) capable of performing specified operations when operating. A module includes hardware. In an example, the hardware may be specifically configured to carry out a specific operation (e.g., hardwired). In another example, the hardware may include configurable execution units (e.g., transistors, circuits, etc.) and a computer-readable medium containing instructions where the instructions configure the execution units to carry out a specific operation when in operation. The configuring may occur under the direction of the execution units or a loading mechanism. Accordingly, the execution units are communicatively coupled to the computer-readable medium when the device is operating. In this example, the execution units may be a member of more than one module. For example, under operation, the execution units may be configured by a first set of instructions to implement a first module at one point in time and reconfigured by a second set of instructions to implement a second module at a second point in time.

Certain embodiments may be implemented in one or a combination of hardware, firmware, and software. Other embodiments may also be implemented as program code or instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media. In some embodiments, the robotic machine 1700 may include one or more processors and may be configured with program code instructions stored on a computer-readable storage device memory. Program code and/or executable instructions embodied on a computer-readable medium may be transmitted using any appropriate medium including, but not limited to, wireless, wireline, optical fiber cable, RF, etc., or any suitable combination of the foregoing. Program code and/or executable instructions for carrying out operations for aspects of the disclosure may be written in any combination of one or more programming languages, including an object-oriented programming language such as Java, Smalltalk, C++ or the like, and conventional procedural programming languages, such as the “C” programming language or similar programming languages. The program code and/or executable instructions may execute entirely on a device, partly on the device, as a stand-alone software package, partly on the device and partly on a remote device or entirely on the remote device or server.

The machine 1700 may include at least one hardware processor 1702 (e.g., a central processing unit (CPU), a graphics processing unit (GPU), a hardware processor core, or any combination thereof), a main memory 1704, and a static memory 1706. The machine 1700 may include drive circuitry 1718. The machine 1700 may further include an inertial measurement device 1732, a graphics display device 1710, an alphanumeric input device 1712 (e.g., a keyboard), and a user interface (UI) navigation device 1714 (e.g., a mouse). In an example, the graphics display device 1710, the alphanumeric input device 1712, and the UI navigation device 1714 may be a touch screen display. The machine 1700 may additionally include a storage device 1716, a TCB control device (e.g., capable of controlling the STA, BS, and bond head and shown/described herein), a network interface device/transceiver 1720 coupled to antenna(s) 1730, and one or more sensors 1728. The machine 1700 may include an output controller 1734, such as a serial (e.g., universal serial bus (USB), parallel, or other wired or wireless (e.g., infrared (IR), near field communication (NFC), etc.) connection to communicate with or control one or more peripheral devices. These components may couple and may communicate with each other through an interlink (e.g., bus) 1708. Further, the machine 1700 may include a power supply device that is capable of supplying power to the various components of the machine 1700.

The drive circuitry 1718 may include a motor driver circuitry that operates various motors associated with the axes of the machine 1700. Motors may facilitate the movement and positioning of the robotic machine 1700 around the respective axes for a plurality of degrees of freedom (e.g., X, Y, Z, pitch, yaw, and roll). The motor driver circuitry may track and modify the positions around the axes by affecting the respective motors.

The inertial measurement device 1732 may provide orientation information associated with a plurality of degrees of freedom (e.g., X, Y, Z, pitch, yaw, roll, roll rate, pitch rate, yaw rate) to the hardware processor 1702. The hardware processor 1702 may in turn analyze the orientation information and generate, possibly using both the orientation information and the encoder information regarding the motor shaft positions, control signals for each motor. These control signals may, in turn, be communicated to motor amplifiers to independently control motors to impart a force on the system to move the system. The control signals may control motors to move a motor to counteract, initiate, or maintain rotation.

The hardware processor 1702 may be capable of communicating with and independently sending control signals to a plurality of motors associated with the axes of the machine 1700.

The storage device 1716 may include a machine-readable medium 1722 on which is stored one or more sets of data structures or instructions 1724 (e.g., software) embodying or utilized by any one or more of the techniques or functions described herein. The instructions 1724 may also reside, completely or at least partially, within the main memory 1704, within the static memory 1706, or within the hardware processor 1702 during execution thereof by the machine 1700. In an example, one or any combination of the hardware processor 1702, the main memory 1704, the static memory 1706, or the storage device 1716 may constitute machine-readable media.

The antenna(s) 1730 may include one or more directional or omnidirectional antennas, including, for example, dipole antennas, monopole antennas, patch antennas, loop antennas, microstrip antennas, or other types of antennas suitable for the transmission of RF signals. In some embodiments, instead of two or more antennas, a single antenna with multiple apertures may be used. In these embodiments, each aperture may be considered a separate antenna. In some multiple-input multiple-output (MIMO) embodiments, the antennas may be effectively separated for spatial diversity and the different channel characteristics that may result between each of the antennas and the antennas of a transmitting station.

The TCB control device 1719 may carry out or perform any of the operations and processes (e.g., the process 1600) described and shown above.

It is understood that the above are only a subset of what the TCB control device 1719 may be configured to perform and that other functions included throughout this disclosure may also be performed by the TCB control device 1719.

While the machine-readable medium 1722 is illustrated as a single medium, the term “machine-readable medium” may include a single medium or multiple media (e.g., a centralized or distributed database, and/or associated caches and servers) configured to store the one or more instructions 1724.

Various embodiments may be implemented fully or partially in software and/or firmware. This software and/or firmware may take the form of instructions contained in or on a non-transitory computer-readable storage medium. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random-access memory (RAM), magnetic disk storage media; optical storage media’ a flash memory, etc.

The term “machine-readable medium” may include any medium that is capable of storing, encoding, or carrying instructions for execution by the robotic machine 1700 and that cause the robotic machine 1700 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium includes a machine-readable medium with a plurality of particles having resting mass. Specific examples of massed machine-readable media may include non-volatile memory, such as semiconductor memory devices (e.g., electrically programmable read-only memory (EPROM), or electrically erasable programmable read-only memory (EEPROM)) and flash memory devices; magnetic disks, such as internal hard disks and removable disks; magneto-optical disks; and CD-ROM and DVD-ROM disks.

The instructions 1724 may further be transmitted or received over a communications network 1726 using a transmission medium via the network interface device/transceiver 1320 utilizing any one of a number of transfer protocols (e.g., frame relay, internet protocol (IP), transmission control protocol (TCP), user datagram protocol (UDP), hypertext transfer protocol (HTTP), etc.). Example communications networks may include a local area network (LAN), a wide area network (WAN), a packet data network (e.g., the Internet), mobile telephone networks (e.g., cellular networks), plain old telephone (POTS) networks, wireless data networks (e.g., Institute of Electrical and Electronics Engineers (IEEE) 802.11 family of standards known as Wi-Fi®, and peer-to-peer (P2P) networks, among others. In an example, the network interface device/transceiver 1720 may include one or more physical jacks (e.g., Ethernet, coaxial, or phone jacks) or one or more antennas (e.g., antennas 1730) to connect to the communications network 1726. In an example, the network interface device/transceiver 1720 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the robotic machine 1700 and includes digital or analog communications signals or other intangible media to facilitate communication of such software. The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories that provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions that, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chipset, memory, or the like. Integrated circuits include circuits created on a substrate such as a silicon wafer and may comprise components. Integrated circuits, processor packages, chip packages, and chipsets may comprise one or more processors.

Processors may receive signals such as instructions and/or data at the input(s) and process the signals to generate at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, a smartphone, a tablet, a netbook, a wireless terminal, a laptop computer, a femtocell, a high data rate (HDR) subscriber station, an access point, a printer, a point of sale device, an access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as “communicating,” when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

Some embodiments may be used in conjunction with various devices and systems, for example, a personal computer (PC), a desktop computer, a mobile computer, a laptop computer, a notebook computer, a tablet computer, a server computer, a handheld computer, a handheld device, a personal digital assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless access point (AP), a wired or wireless router, a wired or wireless modem, a video device, an audio device, an audio-video (A/V) device, a wired or wireless network, a wireless area network, a wireless video area network (WVAN), a local area network (LAN), a wireless LAN (WLAN), a personal area network (PAN), a wireless PAN (WPAN), and the like.

Some embodiments may be used in conjunction with one way and/or two-way radio communication systems, cellular radio-telephone communication systems, a mobile phone, a cellular telephone, a wireless telephone, a personal communication system (PCS) device, a PDA device which incorporates a wireless communication device, a mobile or portable global positioning system (GPS) device, a device which incorporates a GPS receiver or transceiver or chip, a device which incorporates an RFID element or chip, a multiple input multiple output (MIMO) transceiver or device, a single input multiple output (SIMO) transceiver or device, a multiple input single output (MISO) transceiver or device, a device having one or more internal antennas and/or external antennas, digital video broadcast (DVB) devices or systems, multi-standard radio devices or systems, a wired or wireless handheld device, e.g., a smartphone, a wireless application protocol (WAP) device, or the like.

Some embodiments may be used in conjunction with one or more types of wireless communication signals and/or systems following one or more wireless communication protocols, for example, radio frequency (RF), infrared (IR), frequency-division multiplexing (FDM), orthogonal FDM (OFDM), time-division multiplexing (TDM), time-division multiple access (TDMA), extended TDMA (E-TDMA), general packet radio service (GPRS), extended GPRS, code-division multiple access (CDMA), wideband CDMA (WCDMA), CDMA 2000, single-carrier CDMA, multi-carrier CDMA, multi-carrier modulation (MDM), discrete multi-tone (DMT), Bluetooth®, global positioning system (GPS), Wi-Fi, Wi-Max, ZigBee, ultra-wideband (UWB), global system for mobile communications (GSM), 2G, 2.5G, 3G, 3.5G, 4G, fifth generation (5G) mobile networks, 3GPP, long term evolution (LTE), LTE advanced, enhanced data rates for GSM Evolution (EDGE), or the like. Other embodiments may be used in various other devices, systems, and/or networks.

The following examples pertain to further embodiments.

Example 1 may include method for thermal compression bonding of integrated process using enhanced substrate transfer arm (STA) and bond stage designs, the method comprising: picking up, using suction cups of a substrate transfer arm (STA) comprising multiple rows of suction cups, a first substrate row from a first row of a tray; placing, using the suction cups, the first substrate row onto a first row of a bond stage corresponding to the first row of the tray; picking up, using the suction cups, a second substrate row from the tray; moving the STA to a position associated with the bond stage; placing, using the suction cups, the second substrate row onto a remaining empty row of the bond stage different than the first row of the bond stage from which the first substrate row or another substrate row is picked up after bonding; picking up, using the suction cups, the first substrate row after thermal bonding or the another substrate row after thermal bonding from the bond stage; placing, using the suction cups, the first substrate row after thermal bonding or the another substrate row after thermal bonding onto the tray; when all substrates from the tray have been thermally bonded, picking up, using the suction cups, a last substrate row after thermal bonding from the bond stage; and placing, using the suction cups, the last substrate row onto the tray.

Example 2 may include the method of example 1 and/or any other example herein, wherein picking up the second substrate row, moving the STA to the position associated with the bond stage, and placing the second substrate row onto the remaining empty row of the bond stage different than the row from which the STA picked up the first substrate row from the tray occur during a preheating of at least one of the first substrate row or the another substrate row for thermal compression bonding.

Example 3 may include the method of example 1 and/or any other example herein, wherein picking up the second substrate row, moving the STA to the position associated with the bond stage, and placing the second substrate row occur sequentially after thermal bonding has been completed on a remaining substrate row on the bond stage.

Example 4 may include the method of example 1 and/or any other example herein, further comprising: before all substrates from the tray have been thermally bonded, picking up, using the suction cups, an additional substrate row from the tray; moving the STA to a second position associated with the bond stage; placing, using the suction cups, the additional substrate row onto the remaining empty row on the bond stage; picking, using the suction cups, a completed bonding substrate row from a row of the tray different than the row from which the STA placed the additional substrate row from the bond stage; and placing, using the suction cups, the first substrate row after thermal bonding onto a row of the tray different than the row from which the STA picked up a completed substrate row from the bond stage.

Example 5 may include the method of example 1 and/or any other example herein, wherein the second substrate row is picked up from a first row of the tray corresponding to the first row of the bond stage.

Example 6 may include the method of claim 1 and/or any other example herein, wherein the substrate row is picked up from a second row of the tray not corresponding to the first row of the bond stage.

Example 7 may include the method of example 1 and/or any other example herein, wherein the first row or i-th row is based on a row-pattern index mapping from a respective row of the tray to a respective row of the bond stage.

Example 8 may include a substrate transfer arm (STA) for thermal compression bonding, the STA comprising multiple rows of suction cups, the STA configured to: pick up, using the suction cups, a first substrate row from a first row of a tray; place, using the suction cups, the first substrate row onto a first row of a bond stage corresponding to the first row of the tray; pick up a second substrate row from the tray; move to a position associated with the bond stage; place, using the suction cups, the second substrate row onto a remaining empty row of the bond stage different than the first row of the bond stage from which the first substrate row or another substrate row is picked up after bonding; pick up, using the suction cups, the first substrate row after thermal bonding or another substrate row after thermal bonding from the bond stage; place, using the suction cups, the first substrate row after thermal bonding or the another substrate row after thermal bonding onto the tray; when all substrates from the tray have been thermally bonded, pick up, using the suction cups, a last substrate row after thermal bonding from the bond stage; and place, using the suction cups, the last substrate row onto the tray.

Example 9 may include the STA of example 8 and/or any other example herein, wherein to pick up the second substrate row, move to the position associated with the bond stage, and place the second substrate row onto the remaining empty row of the bond stage different than the row from which the STA picked up the first substrate row from the tray occur during a preheating of at least one of the first substrate row or a previous substrate row for thermal compression bonding.

Example 10 may include the STA of example 8 and/or any other example herein, wherein to pick up the second substrate row, to move to the position associated with the bond stage, to place the second substrate row occur sequentially after thermal bonding has been completed on a remaining substrate row on the bond stage.

Example 11 may include the STA of example 8 and/or any other example herein, wherein the STA is further configured to: before all substrates from the tray have been thermally bonded, pick up, using the suction cups, an additional substrate row from the tray; move to a second position associated with the bond stage; place, using the suction cups, the additional substrate row onto the remaining empty row on the bond stage; pick up, using the suction cups, a completed bonding substrate row from a row of the tray different than the row from which the STA placed the additional substrate row from the bond stage; and place, using the suction cups, the first substrate row after thermal bonding onto a row of the tray different than the row from which the STA picked up a completed substrate row from the bond stage.

Example 12 may include a system for device thermal compression bonding of integrated circuits, the system comprising: a substrate transfer arm (STA) comprising multiple rows of suction cups configured to pick and place substrate rows; a tray from which the STA is configured to pick and place the substrate rows; and a bond stage from which the STA is configured to pick and place the substrate rows; wherein the STA is configured to: pick up, using the suction cups, a first substrate row from a first row of the tray; place, using the suction cups, the first substrate row onto a first row of the bond stage corresponding to the first row of the tray; pick up a second substrate row from the tray; move to a position associated with the bond stage; place, using the suction cups, the second substrate row onto a remaining empty row of the bond stage different than the first row of the bond stage from which the first substrate row or another substrate row is picked up after bonding; pick up, using the suction cups, the first substrate row after thermal bonding or another substrate row after thermal bonding from the bond stage; place, using the suction cups, the first substrate row after thermal bonding or the another substrate row after thermal bonding onto the tray; when all substrates from the tray have been thermally bonded, pick up, using the suction cups, a last substrate row after thermal bonding from the bond stage; and place, using the suction cups, the last substrate row onto the tray.

Example 13 may include the system of example 12 and/or any other example herein, wherein the STA comprises: a two-row pattern comprising four rows of the suction cups configured to pick up and place two substrate rows separately during a same cycle; and a two-vacuum groove system configured to control vacuum suction independently for the two-row pattern during the same cycle.

Example 14 may include the system of example 13 and/or any other example herein, wherein a pedestal of the bond stage comprises: a two-row pattern on a pedestal surface associated with the STA picking up and placing two substrate rows separately on the pedestal during a same cycle; and a two-vacuum groove system configured to control vacuum suction for the two-row pattern.

Example 15 the system of example 14 and/or any other example herein, wherein: vacuum channels of the two-vacuum grove system is configured to supply vacuum and control for each of the rows in the two-row pattern of the STA, a first vacuum channel of the vacuum channels is aligned with the two-row pattern of the STA, and is configured to provide vacuum suction to all suction cups of a first row of the two-row pattern of the STA, a second vacuum channel of the vacuum channels is aligned with the two-row pattern of the STA, and is configured to provide vacuum suction to all suction cups of a second row of the two-row pattern of the STA, the first vacuum channel and the second vacuum channel are configured to provide vacuum suction sequentially for the STA to pick up and place substrate rows between the tray in the pedestal.

Example 16 may include the system of example 14 and/or any other example herein, wherein: two vacuum channels of the two-vacuum groove system of the pedestal per four vacuum channels of the two-vacuum groove system of the pedestal are configured to supply vacuum suction and control for each row of the two-row pattern of the pedestal, a first vacuum channel of the two vacuum channels and a second vacuum channel of the two vacuum channels are aligned with the a first row-pattern of the two-row pattern of the pedestal, and are configured to provide the vacuum suction, a third vacuum channel and a fourth vacuum channel of the four vacuum channels are aligned with the first row-pattern of the two-row pattern of the pedestal, and are configured to provide the vacuum suction, the four vacuum channels are configured to provide vacuum suction to sequentially.

Example 17 may include the system of example 12 and/or any other example herein, wherein: the STA comprises a first dimension associated with a first keep-out-zone (KOZ) for a short edge associated with arranging the row-patterns of the STA, the STA comprises a second dimension associated with a second KOZ for a first long edge associated with the row-patterns of the STA, and the STA comprises a third dimension associated with a third KOZ for a second long edge associated with the row-patterns of the STA.

Example 18 may include the system of example 12 and/or any other example herein, wherein the STA is configured to: map an index of each row-pattern of the STA to each row-pattern of a pedestal of the bond stage and each row of the tray; and calibrate offsets for picking up and placing the substrate rows.

Example 19 may include the system of example 12 and/or any other example herein, wherein to pick up the second substrate row, to move to the position associated with the bond stage, and to place the second substrate row onto the remaining empty row of the bond stage different than the row from which the STA picked up the first substrate row from the tray occur during a preheating of at least one of the first substrate row or a previous substrate row for thermal compression bonding.

Example 20 may include the system of example 12 and/or any other example herein, wherein to pick up the second substrate row, to move to the position associated with the bond stage, and to place the second substrate row occur sequentially after thermal bonding has been completed on a remaining substrate row on the bond stage.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for thermal compression bonding of integrated process using enhanced substrate transfer arm (STA) and bond stage designs, the method comprising:
picking up, using suction cups of a substrate transfer arm (STA) comprising multiple rows of suction cups, a first substrate row from a first row of a tray;
placing, using the suction cups, the first substrate row onto a first row of a bond stage corresponding to the first row of the tray;
picking up, using the suction cups, a second substrate row from the tray;
moving the STA to a position associated with the bond stage;
placing, using the suction cups, the second substrate row onto a remaining empty row of the bond stage different than the first row of the bond stage from which the first substrate row or another substrate row is picked up after bonding;
picking up, using the suction cups, the first substrate row after thermal bonding or the another substrate row after thermal bonding from the bond stage;
placing, using the suction cups, the first substrate row after thermal bonding or the another substrate row after thermal bonding onto the tray;
when all substrates from the tray have been thermally bonded, picking up, using the suction cups, a last substrate row after thermal bonding from the bond stage; and
placing, using the suction cups, the last substrate row onto the tray.

2. The method of claim 1, wherein picking up the second substrate row, moving the STA to the position associated with the bond stage, and placing the second substrate row onto the remaining empty row of the bond stage different than the row from which the STA picked up the first substrate row from the tray occur during a preheating of at least one of the first substrate row or the another substrate row for thermal compression bonding.

3. The method of claim 1, wherein picking up the second substrate row, moving the STA to the position associated with the bond stage, and placing the second substrate row occur sequentially after thermal bonding has been completed on a remaining substrate row on the bond stage.

4. The method of claim 1, further comprising:
before all substrates from the tray have been thermally bonded, picking up, using the suction cups, an additional substrate row from the tray;
moving the STA to a second position associated with the bond stage;
placing, using the suction cups, the additional substrate row onto the remaining empty row on the bond stage;
picking, using the suction cups, a completed bonding substrate row from a row of the tray different than the row from which the STA placed the additional substrate row from the bond stage; and
placing, using the suction cups, the first substrate row after thermal bonding onto a row of the tray different than the row from which the STA picked up a completed substrate row from the bond stage.

5. The method of claim 1, wherein the second substrate row is picked up from a first row of the tray corresponding to the first row of the bond stage.

6. The method of claim 1, wherein the substrate row is picked up from a second row of the tray not corresponding to the first row of the bond stage.

7. The method of claim 1, wherein the first row or i-th row is based on a row-pattern index mapping from a respective row of the tray to a respective row of the bond stage.

8. A substrate transfer arm (STA) for thermal compression bonding, the STA comprising multiple rows of suction cups, the STA configured to:
pick up, using the suction cups, a first substrate row from a first row of a tray;
place, using the suction cups, the first substrate row onto a first row of a bond stage corresponding to the first row of the tray;
pick up a second substrate row from the tray;
move to a position associated with the bond stage;
place, using the suction cups, the second substrate row onto a remaining empty row of the bond stage different than the first row of the bond stage from which the first substrate row or another substrate row is picked up after bonding;
pick up, using the suction cups, the first substrate row after thermal bonding or another substrate row after thermal bonding from the bond stage;
place, using the suction cups, the first substrate row after thermal bonding or the another substrate row after thermal bonding onto the tray;
when all substrates from the tray have been thermally bonded, pick up, using the suction cups, a last substrate row after thermal bonding from the bond stage; and
place, using the suction cups, the last substrate row onto the tray.

9. The STA of claim 8, wherein to pick up the second substrate row, move to the position associated with the bond stage, and place the second substrate row onto the remaining empty row of the bond stage different than the row from which the STA picked up the first substrate row from the tray occur during a preheating of at least one of the first substrate row or a previous substrate row for thermal compression bonding.

10. The STA of claim 8, wherein to pick up the second substrate row, to move to the position associated with the bond stage, to place the second substrate row occur sequentially after thermal bonding has been completed on a remaining substrate row on the bond stage.

11. The STA of claim 8, wherein the STA is further configured to:
before all substrates from the tray have been thermally bonded, pick up, using the suction cups, an additional substrate row from the tray;
move to a second position associated with the bond stage;
place, using the suction cups, the additional substrate row onto the remaining empty row on the bond stage;
pick up, using the suction cups, a completed bonding substrate row from a row of the tray different than the row from which the STA placed the additional substrate row from the bond stage; and
place, using the suction cups, the first substrate row after thermal bonding onto a row of the tray different than the row from which the STA picked up a completed substrate row from the bond stage.

12. A system for device thermal compression bonding of integrated circuits, the system comprising:
a substrate transfer arm (STA) comprising multiple rows of suction cups configured to pick and place substrate rows;
a tray from which the STA is configured to pick and place the substrate rows; and
a bond stage from which the STA is configured to pick and place the substrate rows; wherein the STA is configured to:
pick up, using the suction cups, a first substrate row from a first row of the tray;
place, using the suction cups, the first substrate row onto a first row of the bond stage corresponding to the first row of the tray;
pick up a second substrate row from the tray;
move to a position associated with the bond stage;
place, using the suction cups, the second substrate row onto a remaining empty row of the bond stage different than the first row of the bond stage from which the first substrate row or another substrate row is picked up after bonding;
pick up, using the suction cups, the first substrate row after thermal bonding or another substrate row after thermal bonding from the bond stage;
place, using the suction cups, the first substrate row after thermal bonding or the another substrate row after thermal bonding onto the tray;
when all substrates from the tray have been thermally bonded, pick up, using the suction cups, a last substrate row after thermal bonding from the bond stage; and
place, using the suction cups, the last substrate row onto the tray.

13. The system of claim 12, wherein the STA comprises:
a two-row pattern comprising four rows of the suction cups configured to pick up and place two substrate rows separately during a same cycle; and
a two-vacuum groove system configured to control vacuum suction independently for the two-row pattern during the same cycle.

14. The system of claim 13, wherein a pedestal of the bond stage comprises:
a two-row pattern on a pedestal surface associated with the STA picking up and placing two substrate rows separately on the pedestal during a same cycle; and
a two-vacuum groove system configured to control vacuum suction for the two-row pattern.

15. The system of claim 14, wherein:
vacuum channels of the two-vacuum grove system is configured to supply vacuum and control for each of the rows in the two-row pattern of the STA,
a first vacuum channel of the vacuum channels is aligned with the two-row pattern of the STA, and is configured to provide vacuum suction to all suction cups of a first row of the two-row pattern of the STA,
a second vacuum channel of the vacuum channels is aligned with the two-row pattern of the STA, and is configured to provide vacuum suction to all suction cups of a second row of the two-row pattern of the STA,
the first vacuum channel and the second vacuum channel are configured to provide vacuum suction sequentially for the STA to pick up and place substrate rows between the tray in the pedestal.

16. The system of claim 14, wherein:
two vacuum channels of the two-vacuum groove system of the pedestal per four vacuum channels of the two-vacuum groove system of the pedestal are configured to supply vacuum suction and control for each row of the two-row pattern of the pedestal,
a first vacuum channel of the two vacuum channels and a second vacuum channel of the two vacuum channels are aligned with the a first row-pattern of the two-row pattern of the pedestal, and are configured to provide the vacuum suction,
a third vacuum channel and a fourth vacuum channel of the four vacuum channels are aligned with the first row-pattern of the two-row pattern of the pedestal, and are configured to provide the vacuum suction,
the four vacuum channels are configured to provide vacuum suction to sequentially.

17. The system of claim 12, wherein:
the STA comprises a first dimension associated with a first keep-out-zone (KOZ) for a short edge associated with arranging the row-patterns of the STA,
the STA comprises a second dimension associated with a second KOZ for a first long edge associated with the row-patterns of the STA, and
the STA comprises a third dimension associated with a third KOZ for a second long edge associated with the row-patterns of the STA.

18. The system of claim 12, wherein the STA is configured to:
map an index of each row-pattern of the STA to each row-pattern of a pedestal of the bond stage and each row of the tray; and
calibrate offsets for picking up and placing the substrate rows.

19. The system of claim 12, wherein to pick up the second substrate row, to move to the position associated with the bond stage, and to place the second substrate row onto the remaining empty row of the bond stage different than the row from which the STA picked up the first substrate row from the tray occur during a preheating of at least one of the first substrate row or a previous substrate row for thermal compression bonding.

20. The system of claim 12, wherein to pick up the second substrate row, to move to the position associated with the bond stage, and to place the second substrate row occur sequentially after thermal bonding has been completed on a remaining substrate row on the bond stage.
